(19) United States
(12) Patent Application Publication
(10) Pub. No.: US 2026/0262271 A1
(43) Pub. Date: Sep. 3, 2026

(54) GROUP III-N DEVICES WITH BUFFER STRUCTURES AND METHODS OF MANUFACTURING THE SAME

(71) Applicant: TEXAS INSTRUMENTS INCORPORATED, Dallas, TX (US)

(72) Inventors: Chan Kyung Choi, Dallas, TX (US); Dong Seup Lee, Allen, TX (US); Yoganand Saripalli, Allen, TX (US); Chang Soo Suh, Allen, TX (US); Hyunsoo Lee, Dallas, TX (US); Qhalid Fareed, Plano, TX (US); Asad M. Haider, Plano, TX (US)

(21) Appl. No.: 19/067,742

(22) Filed: Feb. 28, 2025

(51) Int. Cl. H10D 62/815; H10D 30/01; H10D 30/47; H10D 62/85; H10D 64/00

(52) U.S. Cl. CPC H10D 62/8164; H10D 30/015; H10D 30/475; H10D 62/8503; H10D 64/111

(57) ABSTRACT

A device is disclosed herein. The device includes a substrate, a III-N barrier layer over the substrate, a III-N channel layer underneath the III-N barrier layer, and a III-N buffer layer underneath the III-N channel layer. The III-N channel layer includes 2-dimensional electron gas (2DEG). The III-N buffer layer includes a first structure and a second structure such that the first structure is underneath the second structure. The first structure has a first carbon concentration and the second structure has a second carbon concentration. The second carbon concentration is at least two orders of magnitude greater than the first carbon concentration.

### CROSS-REFERENCE TO RELATED APPLICATION

This application is related to co-pending U.S. patent application Ser. No. 19/067,757, filed Feb. 28, 2025, and entitled “GROUP III-N DEVICES WITH BUFFER STRUCTURES AND METHODS OF MANUFACTURING THE SAME,” which is hereby incorporated by reference in its entirety.

### FIELD

The present disclosure generally relates to semiconductor devices, and more particularly, to high electron mobility semiconductor devices.

### BACKGROUND

A type of semiconductor device is a high electron mobility device employing different semiconductor materials to form a heterojunction, where a channel may be formed near the heterojunction and between two terminals. A high electron mobility device may support a high-speed operation, which makes high electron mobility devices attractive for high frequency applications, among others.

### SUMMARY

Disclosed herein is a semiconductor device including a substrate, an aluminum gallium nitride (AlGaN) barrier layer over the substrate, and a gallium nitride (GaN) channel layer underneath the AlGaN barrier layer. The GaN channel layer includes 2-dimensional electron gas (2DEG). The semiconductor device further includes a back-barrier structure underneath the GaN channel layer. The back-barrier structure includes a GaN back-barrier layer underneath the GaN channel layer and a first superlattice (SL) structure underneath the GaN back-barrier layer. The GaN back-barrier layer has a carbon concentration in a first range of carbon concentrations. The first SL structure has a plurality of pairs of alternating a GaN layer and an aluminum nitride (AlN) layer. The first SL structure has a first aluminum average composition and a first carbon concentration in the first range of carbon concentrations.

Also disclosed herein is a semiconductor device including a substrate, an aluminum gallium nitride (AlGaN) barrier layer over the substrate, and a first gallium nitride (GaN) layer underneath the AlGaN barrier layer. The first GaN layer including 2-dimensional electron gas (2DEG). The semiconductor device further includes a second GaN layer underneath the first GaN layer. The second GaN layer has a carbon concentration in a first range of carbon concentrations and the carbon concentration of the second GaN layer is greater than that of the first GaN layer by at least two orders of magnitude. The semiconductor device further includes a first superlattice (SL) structure underneath the second GaN layer. The first SL structure has a plurality of pairs of alternating a GaN layer and an aluminum nitride (AlN) layer and the first SL structure has a first aluminum average composition and a first carbon concentration in the first range of carbon concentrations.

Disclosed herein is a semiconductor device including a substrate and a III-N buffer layer disposed over the substrate. The III-N buffer layer includes a first structure disposed over the substrate and a second structure disposed over the first structure. The first structure includes a first layer having a first carbon concentration. The second structure includes a second layer having a second carbon concentration that is at least two orders of magnitude greater than the first carbon concentration. The semiconductor device further includes a III-N channel layer disposed over the III-N buffer layer.

Also disclosed herein is a method including forming a first portion of a III-N buffer layer over a substrate and forming a second portion of the III-N buffer layer over the first portion of the III-N buffer layer. The first portion of the III-N buffer layer has a first average aluminum concentration and a first carbon concentration. The second portion has a second average aluminum concentration that is less than the first average aluminum concentration and a second carbon concentration that is at least two orders of magnitude greater than the first carbon concentration. The method further includes forming a III-N channel layer over the III-N buffer layer. The III-N channel layer including 2-dimensional electron gas (2DEG).

Also disclosed herein is a method including forming a first superlattice (SL) structure over a substrate, forming a first carbon doped gallium nitride layer over the first SL structure, and forming a III-N channel layer over the first carbon doped gallium nitride layer. The first SL structure has a plurality of pairs of alternating layers of a first carbon doped aluminum gallium nitride layer and a first carbon doped aluminum nitride layer, and the first SL structure has a first aluminum average concentration and a first carbon concentration. The first carbon doped gallium nitride layer has a second carbon concentration that is at least two orders of magnitude greater than the first carbon concentration.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a flow chart for a method of forming a semiconductor device, in accordance with various examples.

FIGS. 2A, 2B, 2C, 2D, 2E, 2F, 2G, 2H, 2I, 2J, 2K, and 2L illustrate cross-section views of a semiconductor device, in accordance with the process of FIG. 1 and the various examples associated therewith.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent example functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function. In some cases, such terms may refer to an amount that is within 10% of the stated value. In other cases, such terms may refer to an amount that is within 25% of the stated value.

The accompanying drawings, and detailed description of the drawings, include reference numerals that may be repeated across multiple examples. The repetition of reference numerals is intended simplicity and clarity of description and is not intended to form or dictate a relationship between different examples described herein. The examples and descriptions provided herein are intended to be illustrative and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two. For example, “on” may be used to indicate direct contact between the two and “over” may be used to indicate one or more intervening layers between the two.

Spatially relative terms such as, for example, “lower,” “upper,” “horizontal,” “vertical,” “above,” “over,” “below,” “beneath,” “underneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

For the purposes of this description, the term “III-N” refers to semiconductor materials in which group III elements, such as aluminum, gallium, and indium, and possibly boron, provide a portion of the atoms in the semiconductor material and nitrogen atoms provide another portion of the atoms in the semiconductor material. Examples of III-N semiconductor materials include gallium nitride, boron gallium nitride, aluminum gallium nitride, indium nitride, and indium aluminum gallium nitride. Additionally, terms describing elemental formulas of materials do not imply a particular stoichiometry of the elements. For example, aluminum gallium nitride may be written as AlGaN, which covers a range of relative proportions of aluminum and gallium.

A high electron mobility device (e.g., a high electron mobility transistor (HEMT)) may be used for a variety of applications, including power switching and high power applications. Generally, a high electron mobility device, such as a GaN device (or a III-N semiconductor device), includes a buffer layer formed over a silicon substrate, and III-N active layers formed over the buffer layer. The III-N active layers may include a channel layer formed over the buffer layer, a barrier layer (which may also be referred to as a carrier supplier layer) formed over the channel layer, and a gate stack formed over the barrier layer. The buffer layer may include any number of layers of any materials that are configured to accommodate lattice mismatch between the silicon substrate and III-N active layers, including the channel layer, the barrier layer, and the gate stack. That is, the buffer layer may be designed to reduce or minimize lattice defect generation and/or propagation into the III-N active layers.

The buffer layer may be used to manage strain in the layers of the high electron mobility device, manage a breakdown voltage of the high electron mobility device, and/or manage a current collapse of the high electron mobility device. Typically, a buffer layer employing thicker layers may provide higher breakdown voltages, or voltage ratings. Also, employing carbon doping within the buffer layer may suppress current collapse. However, employing thicker layers within a buffer layer may cause problems such as cracking and other defects arising in one or more of the III-N active layers of the high electron mobility device. Additionally, an increase in the concentration of carbon in the buffer layer may negatively affect the breakdown voltage, or voltage rating. Accordingly, the buffer layer may be designed to manage the tradeoffs between breakdown voltage and current collapse while also managing the stress in the III-N active layers of the high electron mobility device.

Disclosed herein are devices and methods for forming a III-N buffer layer that manages the tradeoff between breakdown voltage and current collapse as well as stress in the layers of the high electron mobility device. As described in further detail below, a III-N buffer layer of the high electron mobility device is formed for breakdown voltage enhancement and current collapse mitigation (or improving carrier confinement). That is, the methods and devices described herein decouple the enhancement of the breakdown voltage from the mitigation of current collapse while facilitating strain management in III-N buffer layers of high electron mobility devices.

In various examples, the III-N buffer layer may be divided into two partitions, a first partition that may be referred to as a voltage sustaining (or voltage withstanding) partition (e.g., a voltage sustaining structure, a voltage sustaining portion) and a second partition that may be referred to as a back-barrier partition (e.g., a back-barrier structure, a back-barrier portion, composite back-barrier partition). As described in further detail below, the voltage sustaining partition may facilitate breakdown voltage enhancement and the back-barrier partition may facilitate charge carrier (e.g., 2-dimensional electron gas (2DEG)) confinement within a channel layer and current collapse mitigation. The III-N buffer layer or a portion thereof, including one or both partitions, includes multiple III-N material layers (e.g., one or more superlattice structures, one or more step graded layers, etc.), and may be referred to as a III-N composite structure.

The III-N buffer layer may have an average concentration of a group III element in a III-N material layer (e.g., average concentration of aluminum in a superlattice structure or in a step graded layer) decreases through the III-N buffer layer in a direction towards the active layers of the high electron mobility device while a concentration of carbon (C) increases through the III-N buffer layer in the direction towards the active layers of the high electron mobility device. That is, in various examples, the respective changes in the average concentration of the group III element and the concentration of carbon (C) are inverse to each other through the III-N buffer layer.

For the purposes of this description, the term “concentration (or average concentration)” of a group III element in a III-N material layer refers to relative content of the group III element in the III-N material layer excluding N-content that accounts for one-half of the III-N material layer composition. For example, a concentration of a group III element (e.g., aluminum) in a III-N material layer (e.g., Al_{0.29}Ga_{0.71}N) is 29%. The concentration (or average concentration) may also be referred to as a composition (or average composition).

Also, in various examples, a thickness of each superlattice structure (or a thickness of each layer of step graded layers) of the III-N buffer layer may decrease in the direction towards the active layers of the high electron mobility device. This decrease in thickness of the superlattice structures may help to manage strain in the layers of the high electron mobility device. For example, decreasing the respective thicknesses of the layers forming the III-N buffer layer in the direction towards the active layers of the high electron mobility device may reduce or avoid problems such as cracking and other defects arising in one or more of the III-N active layers of the high electron mobility device.

In various examples, the III-N buffer layer disclosed herein may include one or more superlattice structures. As described above, in some examples, the III-N buffer layer may be divided into two partitions, a first partition that is a voltage sustaining partition and a second partition that is a back-barrier partition. As such, in various examples, the one or more superlattice structures (or one or more step graded layers) may be considered as part of one of the two partitions of the III-N buffer layer depending on the implementation of a given superlattice structure. In various examples, each of the superlattice structures may include a plurality of pairs of alternating layers of III-N material layers such as a first III-N material layer and a second III-N material layer. In some examples, the plurality of pairs of alternating layers of III-N material layers have different material compositions (e.g., first III-N material layer has a different material composition than second III-N material layer). In various examples, the plurality of pairs of alternating layers of III-N material layers may be formed of carbon doped aluminum nitride (AlN:C), carbon doped aluminum gallium nitride (AlGaN:C) and/or carbon doped gallium nitride (GaN:C).

Each of the plurality of pairs of alternating layers of III-N material layers of a superlattice structure may be formed in a cyclical processing method using one or more process loops. For example, each plurality of pairs of alternating layers of III-N material layers may be formed such that a first layer of III-N material is formed followed by a second layer of III-N material being formed over the first layer of the III-N material layer. This process of forming alternating layers of III-N material may be repeated until a desired thickness for a given superlattice structure is reached. And, as described above, the respective III-N materials forming each layer within the plurality of pairs of alternating layers of III-N material layers may have a different material composition.

In various examples, the III-N buffer layer may have one or more superlattice structures where each superlattice structure is formed of the plurality of pairs of alternating layers of III-N material layers. As described above, in some examples, the III-N buffer layer may be divided into two partitions, a first partition that is a voltage sustaining partition and a second partition that is a back-barrier partition. As such, in various examples, each of the two partitions of the III-N buffer layer may have one or more superlattice structures that are formed of the plurality of pairs of alternating layers of III-N material layers. In some examples, each superlattice structure may have an average concentration of a group III element (e.g., aluminum (Al)) and a concentration of carbon. As described above, the average concentration of the group III element decreases and the concentration of carbon increases as the III-N buffer layer is formed in the direction towards the active layers of the high electron mobility device. That is, the average concentration of the group III element decreases and the concentration of carbon increases in the direction towards the active layers of the high electron mobility device. In various examples, the average concentration of the group III element (e.g., aluminum) gradually decreases through the III-N buffer layer in the direction towards the active layers of the high electron mobility device. The decrease in average concentration of the group III element (e.g., aluminum) through the III-N buffer layer may facilitate strain management during epitaxial growth and may reduce the formation of cracks or other deformities or defects in the III-N active layers. Additionally, the increase in carbon concentration through the III-N buffer layer may facilitate the mitigation of current collapse in the high electron mobility device.

In various examples, the III-N buffer layer disclosed herein may include one or more step graded layers of III-N materials—e.g., as part of the voltage sustaining partition of the III-N buffer layer. As described in more detail herein, step graded layers of III-N materials include multiple III-N material layers (e.g., AlₓGa₁₋ₓN layer), in which individual III-N material layers have respective concentrations (compositions) of a group III element (e.g., aluminum) different from each other such that a concentration profile (e.g., aluminum concentration profile) throughout the step graded layers of III-N materials resembles a stairstep shape. In various examples, the average concentration of the group III element (e.g., aluminum) gradually decreases between each step graded layer through the III-N buffer layer in the direction towards the active layers of the high electron mobility device. In various examples, while the average concentration of the group III element decreases through the III-N buffer layer, the concentration of the group III element may remain relatively constant between one or more adjacent step graded layers. That is, in some examples, one or more of the step graded layers may have the same concentration of the group III element as adjacent layers such that the concentration of the group III element remains relatively constant across one or more of the step graded layers. In various examples, the one or more step graded layers may be used in combination with one or more superlattice structures.

The methods and devices described herein decouples the enhancement of the breakdown voltage from the mitigation of current collapse (e.g., confining carriers within the channel layer) while facilitating strain management in III-N buffer layers of high electron mobility devices. That is, the methods and devices disclosed herein provide a III-N buffer layer that increases breakdown voltage, decreases the occurrence of current collapse (which may be due to trapping of charge carriers (e.g., electrons) during operation), and manages strain in the layers of the high electron mobility device. In various examples, as described above, the III-N buffer layer may be divided into two partitions, a first partition that is a voltage sustaining partition and a second partition that is a back-barrier partition. As such, the two partitions of the III-N buffer layer decouple the breakdown voltage enhancement (voltage sustaining partition) and current collapse mitigation (back-barrier partition). That is, the one or more layers of the voltage sustaining partition are independent of the one or more layers of the back-barrier partition. This decoupling allows the III-N buffer layer to be customized for different use cases. Furthermore, these benefits enhance device reliability and performance across a wide voltage range, from about 100 V to about 1,200 V. Additionally, the methods and devices described herein may reduce the number of discrete components in an integrated circuit. This may be attributed to the implementation of one or more superlattice structures (or one or more step graded layers) of the III-N buffer layer that are functionally partitioned (e.g., voltage sustaining partition and back-barrier partition) with each superlattice structure (or each layer of the step graded layers) having a different level of carbon concentration and/or group III element concentration (e.g., average concentration) as described herein.

As described above, high electron mobility devices may include HEMT devices. HEMTs can be configured as enhancement-mode (E-mode HEMT) devices or depletion-mode HEMT (D-mode HEMT). The E-mode HEMTs are configured to have the charge carriers (e.g., electrons in two-dimensional electron gas formed in the channel layer) depleted (e.g., absent) under the gate stack resulting in normally OFF devices. The E-mode HEMTs can be turned ON by applying a positive voltage to the gate stack. On the other hand, the D-mode HEMTs are configured to have the charge carriers (e.g., electrons in two-dimensional electron gas formed in the channel layer) present under a gate stack resulting in normally ON devices. The D-mode HEMTs devices can be turned OFF by applying a negative voltage to the gate stack. It is understood that the methods and structures disclosed herein are applicable to both E-mode HEMTs and D-mode HEMTs although descriptions herein are primarily associated with E-mode HEMTs. Furthermore, the descriptions herein may be applied to unidirectional and monolithically integrated bi-directional HEMT devices.

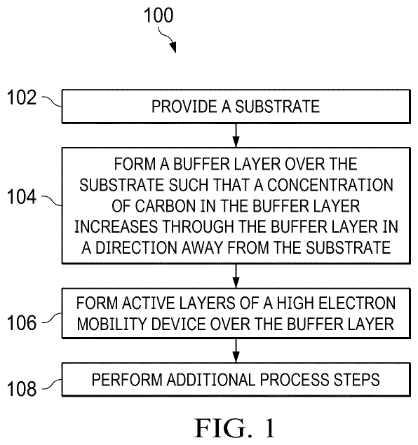

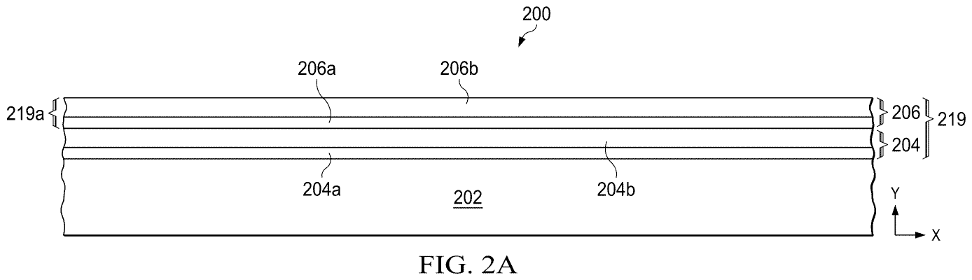

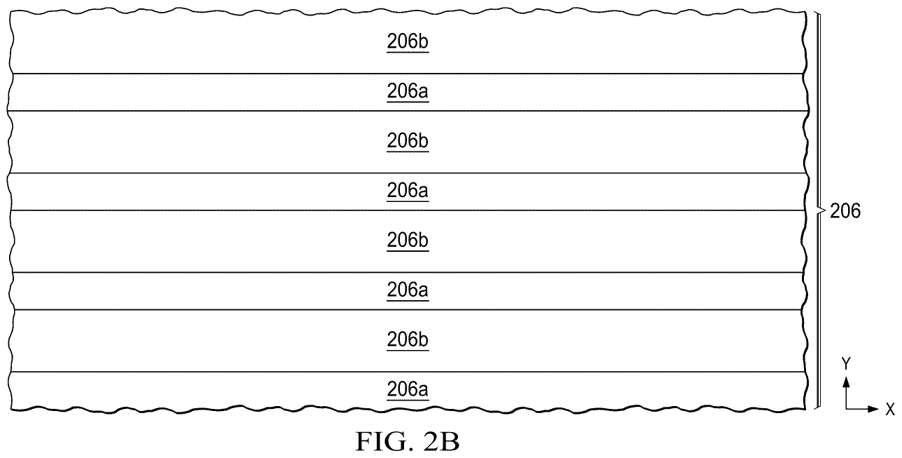

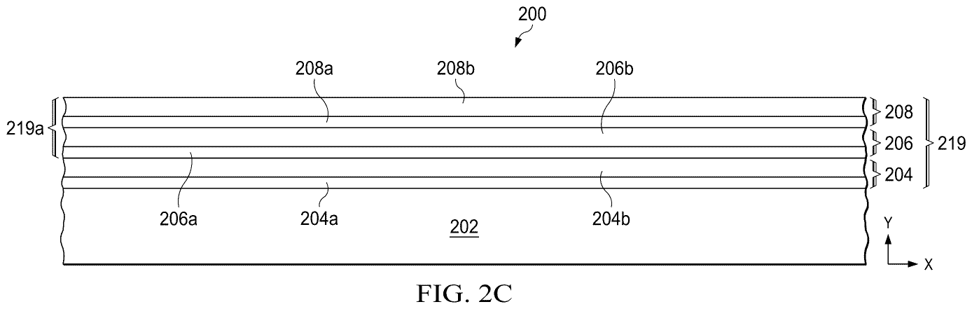

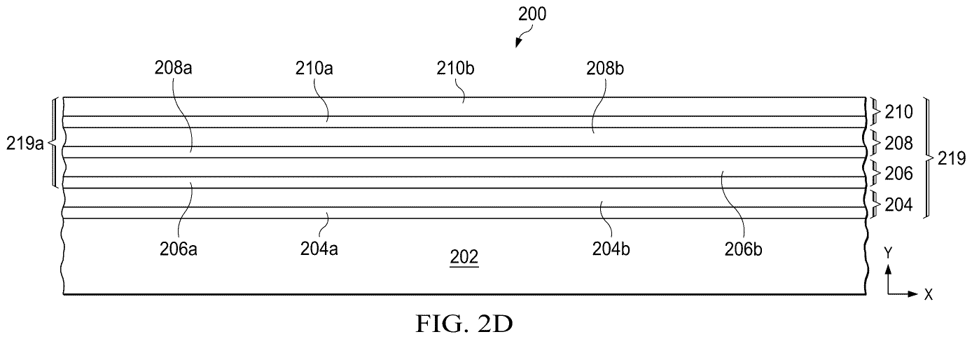

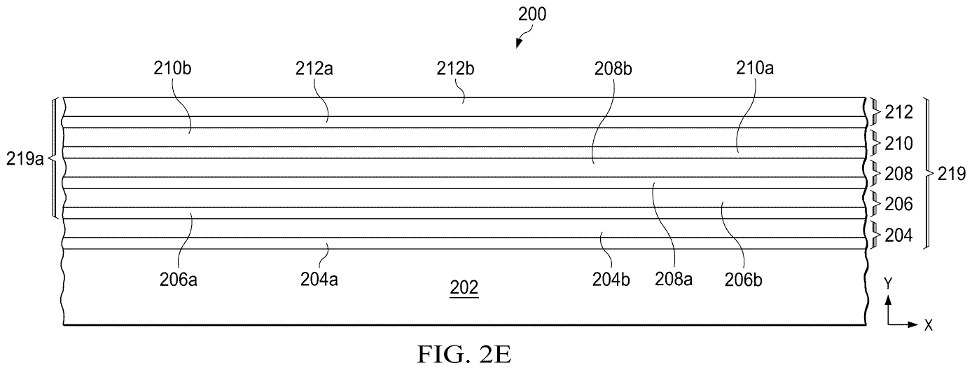

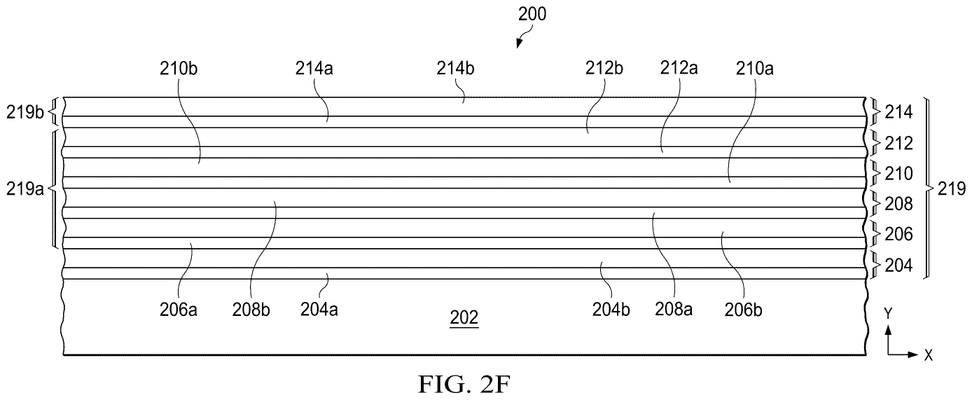

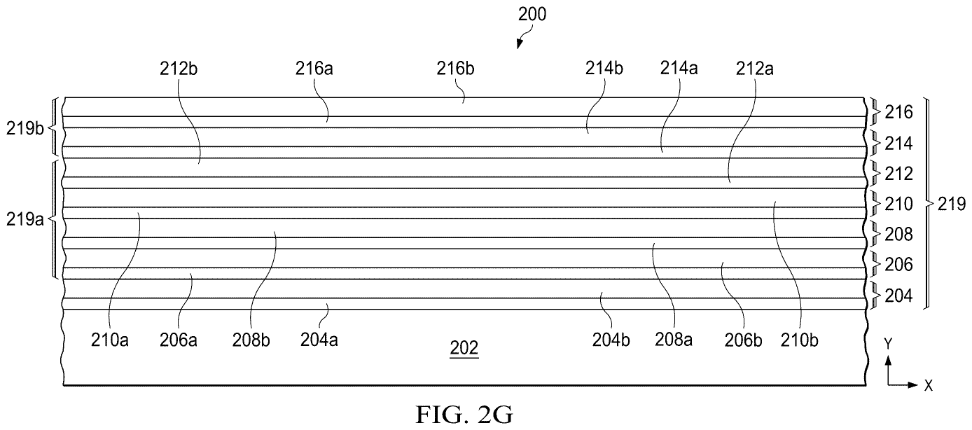

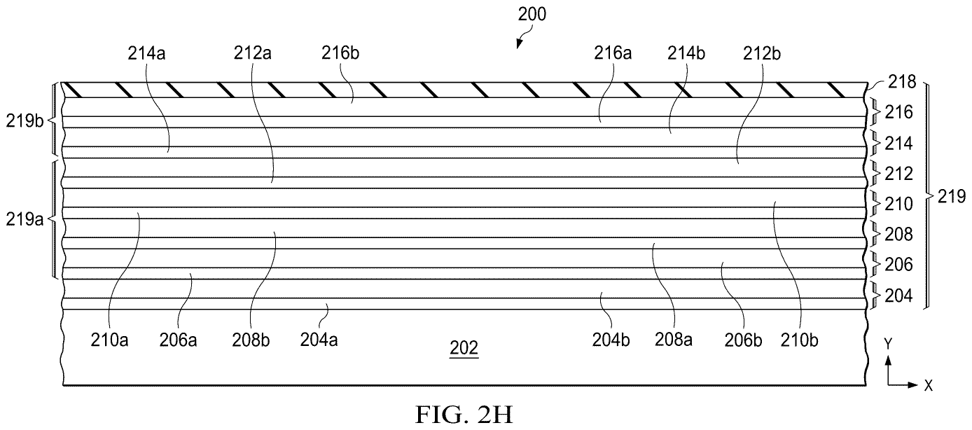

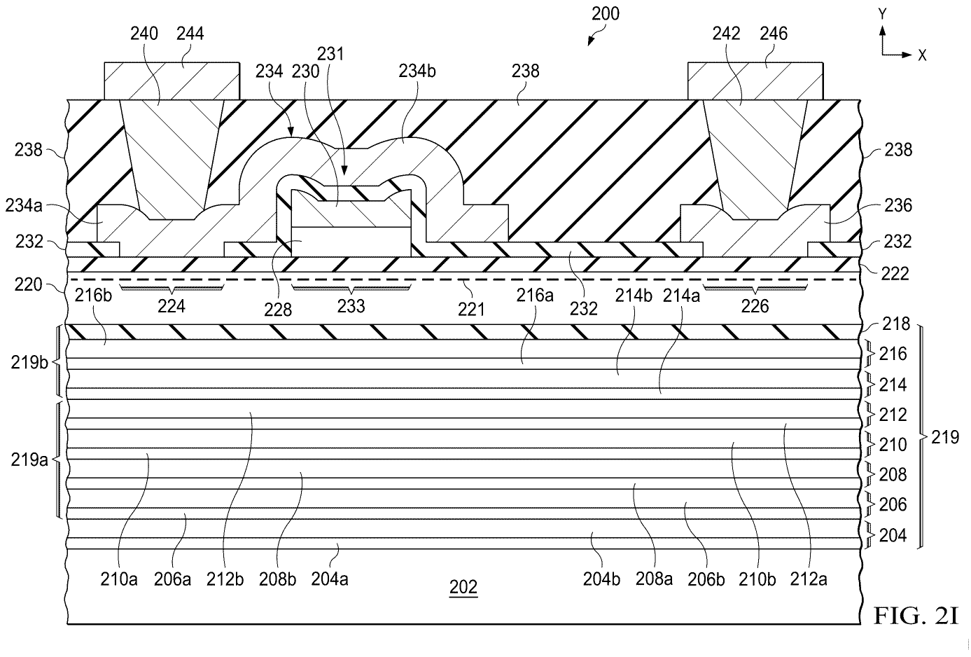

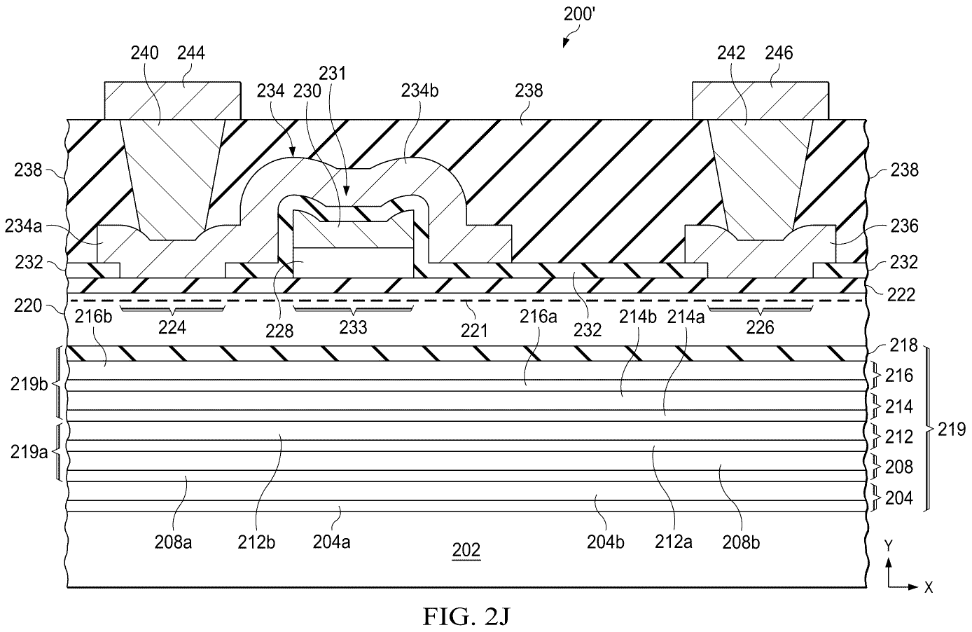

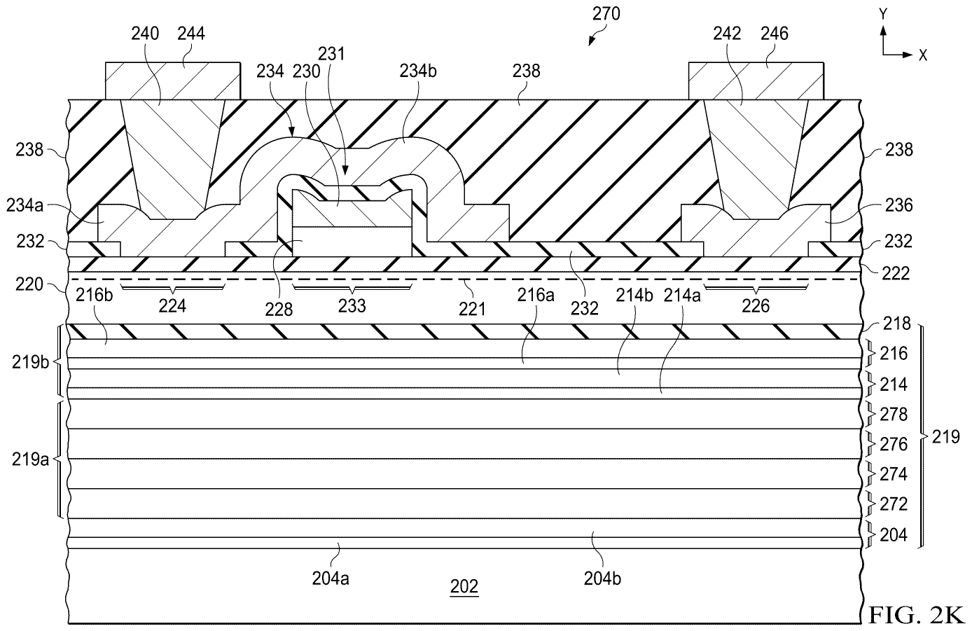

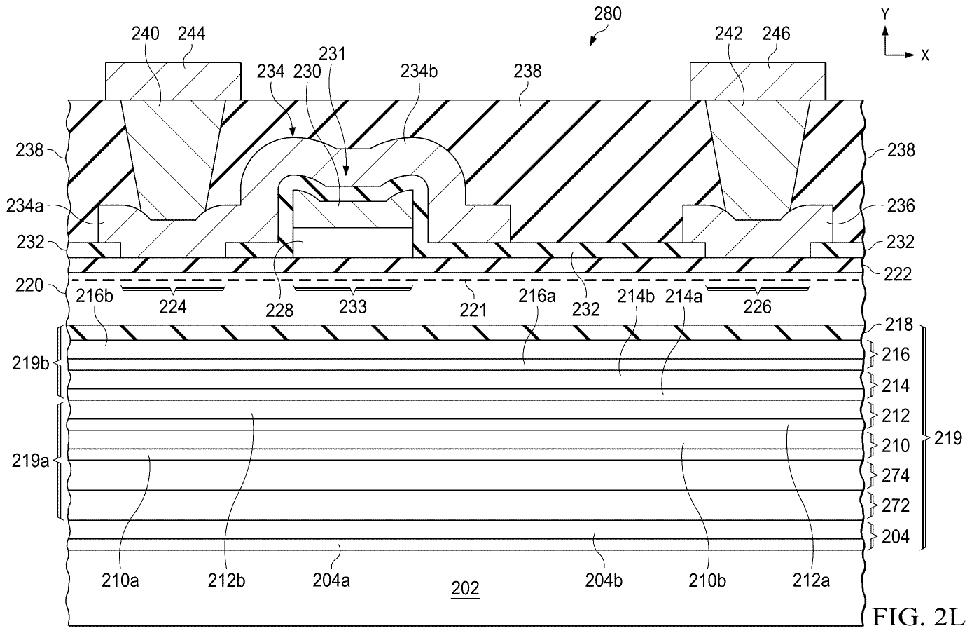

Referring now to FIG. 1, a flow diagram of a method 100 of forming a high electron mobility device having an improved buffer layer is illustrated, in accordance with various examples of the present disclosure. In various examples, method 100 may be used to form a III-N buffer layer to maximize (or increase) voltage ratings and minimize (or decrease) current collapse in semiconductor devices, such as high electron mobility devices (e.g., HEMTs). That is, method 100 allows for the decoupling of the enhancement of the breakdown voltage from the mitigation of current collapse while facilitating strain management in III-N buffer layers of high electron mobility devices. More specifically, in various examples, the III-N buffer layer formed by method 100 may be considered having a first partition that is a voltage sustaining partition and a second partition that is a back-barrier partition. Additional processes can be provided before, during, and after method 100. As described below, method 100 is described with reference to FIGS. 2A-2I.

In that regard, FIGS. 2A-2I are diagrammatic cross-sectional views of a device 200 at various stages of fabrication (such as those associated with method 100 of FIG. 1) according to various aspects of the present disclosure. In various examples, device 200 is or includes an enhancement mode (E-mode) HEMT. Additional features can be added to device 200, and some features described below can be replaced, modified, or eliminated in other examples of device 200.

At step 102 of FIG. 1, a substrate having one or more layers thereover is provided. As shown in FIG. 2A, device 200 includes a substrate 202. Substrate 202 may be a bulk semiconductor substrate, a semiconductor-on-insulator (SOI) substrate, or any other appropriate substrate. For example, the substrate 202 may be or include a bulk silicon wafer. In other examples, substrate 202 may be a silicon carbide substrate, a sapphire substrate, a glass substrate (e.g., borosilicate glass, aluminosilicate glass, and/or fused silica glass), or an engineered substrate configured to support forming various layers thereon (e.g., reducing differences in thermal expansion coefficients). In various examples, substrate 202 may have a thickness of about 600 μm to about 1,500 μm, and more specifically, about 750 μm to about 1,150 μm. For example, when device 200 has a lower voltage rating (e.g., 100 V), substrate 202 may have a thickness of about 600 μm to about 900 μm, and more specifically, about 700 μm to about 800 μm. As another example, when device 200 has a higher voltage rating (e.g., 650 V, 1,200 V), substrate 202 may have a thickness of about 1,000 μm to about 1,300 μm, and more specifically, about 1,100 μm to about 1,200 μm.

At step 104 of FIG. 1, a buffer layer is formed over the substrate such that a concentration of carbon in the buffer layer increases through the buffer layer in a direction away from the substrate. As shown in FIGS. 2A-2H, a III-N buffer layer 219 is formed over substrate 202. III-N buffer layer 219 includes a voltage sustaining partition 219a and a back-barrier partition 219b, as previously described. As described in more detail below, III-N buffer layer 219 may include one or more superlattice structures, one or more step graded layers, or a combination thereof. Each of the one or more superlattice structures and/or one or more step graded layers may be part of voltage sustaining partition 219a or back-barrier partition 219b. For ease of discussion, reference numerals 219, 219a, and 219b will be used to designate III-N buffer layer 219, voltage sustaining partition 219a, and back-barrier partition 219b, respectively, as the buffer layer is formed (grown) in FIGS. 2A-2H. As such, as described in further detail below, III-N buffer layer 219 may include multiple layers, including the one or more superlattice structures, one or more step graded layers, or a combination thereof in each figure. Each superlattice structure of the one or more superlattice structures may be formed from one or more III-N material layers using one or more formation processes as described below. Each superlattice structure of the one or more superlattice structures may be part of either the voltage sustaining partition or the back-barrier partition that are designed to address breakdown voltage enhancement and current collapse mitigation, respectively. Furthermore, the two partitions are independent of each other, decoupling the breakdown voltage enhancement from the current collapse mitigation.

In that regard, base layer 204 is formed over substrate 202. In various examples, base layer 204 may be considered as part of III-N buffer layer 219. More specifically, in some examples, base layer 204 may be considered as part of voltage sustaining partition 219a of III-N buffer layer 219, as described in detail below. In various examples, base layer 204 may be designed to include any number of layers of any materials (e.g., transition layers) that are configured to accommodate the formation of the additional layers of III-N buffer layer 219 thereover. In various examples, base layer 204 includes a first base layer 204a and a second base layer 204b. In various examples, first base layer 204a and second base layer 204b may be or may include one or more elements, such as III-N materials.

In various examples, the one or more elements of first base layer 204a may include aluminum (Al), nitrogen (N₂), and/or other suitable elements. In various examples, first base layer 204a may include aluminum nitride (AlN). In various examples, first base layer 204a may have an aluminum concentration of about 90% to about 100% (e.g., AlN). In various examples, first base layer 204a may be referred to as a nucleation layer. In various examples, second base layer 204b may include aluminum (Al), gallium (Ga), nitrogen (N₂), and/or other suitable elements. In various examples, second base layer 204b may include aluminum gallium nitride (AlGaN). In various examples, second base layer 204b may have an aluminum concentration of about 55% to about 80%, and more specifically, about 60% to about 75% (e.g., Al_{0.67}Ga_{0.33}N).

In various examples, first base layer 204a may have a thickness of about 125 nm to about 410 nm, and more specifically, about 175 nm to about 360 nm. In some examples, when device 200 has a lower voltage rating (e.g., 100 V), the thickness of first base layer 204a may be about 125 nm to about 225 nm, and more specifically, about 150 nm to about 200 nm. In some other examples, when device 200 has a higher voltage rating (e.g., 650 V, 1,200 V), the thickness of first base layer 204a may be about 310 nm to about 410 nm, and more specifically, about 340 nm to about 380 nm. In various examples, the thickness of second base layer 204b may be about 120 nm to about 220 nm, and more specifically, about 150 nm to about 190 nm across several voltage ratings (e.g., 100 V, 650 V, 1,200 V, etc.) for device 200.

In various examples, base layer 204, including first base layer 204a and second base layer 204b, is an undoped layer. In some examples, the material of base layer 204 is or includes an unintentionally doped material, such as a material doped by diffusion of dopants from another layer or low levels of carbon in view of base layers being formed using carbon based metalorganic materials (e.g., trimethylgallium (TMGa, Ga(CH₃)₃, trimethylaluminum (TMA, C₆H₁₈A₁₂)). In various examples, the concentration of dopant in the unintentionally doped material may not be detectable as such is considered an undoped layer. Accordingly, in various examples, base layer 204 may be referred to as an undoped layer or an unintentionally doped (UID) layer. In some examples, base layer 204 includes carbon concentration in the order of about 1×10¹⁵ cm⁻³ or about 1×10¹⁶ cm⁻³.

Next, as shown schematically in FIG. 2A, a first superlattice structure 206 is formed over base layer 204 as part of voltage sustaining partition 219a of III-N buffer layer 219. More specifically, first superlattice structure 206 includes a plurality of alternating pairs of a first III-N material layer 206a and a second III-N material layer 206b. That is, as shown in FIG. 2B, first superlattice structure 206 includes a plurality of alternating pairs of first III-N material layer 206a and second III-N material layer 206b. In various examples, first superlattice structure 206 is formed via a cyclical processing method. For example, a first layer of first III-N material layer 206a is formed over base layer 204 then a first layer of second III-N material layer 206b is formed over the first layer of first III-N material layer 206a. Next a second layer of first III-N material layer 206a is formed over the first layer of second III-N material layer 206b followed by a second layer of second III-N material layer 206b being formed over the second layer of first III-N material layer 206a. This cyclical process, as shown in FIG. 2B, may be repeated any number of times to form first superlattice structure 206. In various examples, and as will be described in further detail below, the cyclical process may be repeated, or looped, many times to achieve a desired, or designed, thickness and/or III-N material concentration in first superlattice structure 206. Furthermore, the forming of the plurality of pairs of III-N material layers, as illustrated in FIG. 2B, is applicable to the forming of other superlattice structures (e.g., second superlattice structure 208, third superlattice structure 210, fourth superlattice structure 212, fifth superlattice structure 214, and/or sixth superlattice structure 216) described further below.

Each first III-N material layer 206a in first superlattice structure 206 includes one or more elements such as a III-N material doped with carbon. In various examples, the one or more elements may include aluminum (Al), nitrogen (N₂), carbon (C), and/or other suitable elements. In various examples, first III-N material layer 206a may include carbon doped aluminum nitride (AlN:C).

In various examples, each layer of first III-N material layer 206a may have a first thickness and a first group III element concentration. In various examples, the first thickness may be about 2 nm to about 8 nm, and more specifically, about 4 nm to about 6 nm. In various examples, first III-N material layer 206a may include carbon doped aluminum nitride (AlN:C) in which the first group III element may be aluminum (e.g., AlN:C) and the aluminum concentration may be about 90% to about 100%.

Each second III-N material layer 206b in first superlattice structure 206 includes one or more elements such as a III-N material doped with carbon. In various examples, the one or more elements may include aluminum (Al), gallium (Ga), nitrogen (N₂), carbon (C), and/or other suitable elements. In various examples, second III-N material layer 206b has a different material composition than first III-N material layer 206a. In various examples, second III-N material layer 206b may include carbon doped aluminum gallium nitride (AlGaN:C).

In various examples, second III-N material layer 206b has a second thickness and a second group III element concentration. In various examples, the second thickness may be about 15 nm to about 25 nm, and more specifically, about 17 nm to about 23 nm. In various examples, the second group III element may be aluminum (e.g., AlGaN:C) and the aluminum concentration may be about 30% to about 40%, and more specifically, about 32% to about 38% (e.g., Al_{0.35}Ga_{0.65}N:C). Aluminum concentration and average aluminum concentration may alternatively be referred to as aluminum composition and average aluminum composition, respectively.

Because of the plurality of pairs of first III-N material layer 206a and second III-N material layer 206b, first superlattice structure 206 has a first superlattice thickness. In various examples, the first superlattice thickness may be about 200 nm to about 400 nm, and more specifically, about 250 nm to about 350 nm, depending on the number of processing loops (e.g., cycles, pairs of layers) performed to form first superlattice structure 206. In various examples, the cyclical process may be repeated about 8 times to about 16 times, and more specifically, about 10 times to about 14 times. In various examples, the first superlattice thickness may be based on the desired (or designed) breakdown voltage of device 200. For example, the first superlattice thickness as described above may be used when device 200 has a higher voltage rating (e.g., 1,200 V). In other examples, when device 200 has a lower voltage rating (e.g., 100 V or 650 V) first superlattice structure 206 may be omitted, as described in more detail below in FIG. 2J.

Additionally, in various examples, the group III element concentration of first superlattice structure 206 may be a weighted average of the group III element across all of first III-N material layers 206a and second III-N material layers 206b forming first superlattice structure 206. That is, the weighted average accounts for the respective thicknesses and group III element concentrations of first III-N material layer 206a and second III-N material layer 206b. Therefore, in some examples, the thicker second III-N material layer 206b having a lower group III element concentration has a greater effect on the average group III element concentration than the thinner first III-N material layer 206a having a higher group III element concentration. In various examples, when the group III element is aluminum in both the first III-N material layers 206a and second III-N material layers 206b the weighted average of aluminum concentration of first superlattice structure 206 may be about 40% to about 55%, and more specifically, about 45% to about 50%.

In various examples, the first carbon concentration of first superlattice structure 206 may be (e.g., vary between) about 1×10¹⁷ cm⁻³ to about 5×10¹⁹ cm⁻³, and more specifically, about 5×10¹⁷ cm⁻³ to about 1×10¹⁹ cm⁻³. In some examples, first superlattice structure 206 may be in situ carbon doped during one or more epitaxial growth processes. In some examples, in situ refers to performing a process (e.g., carbon doping) concurrently with a formation process (e.g., a process of forming a superlattice structure or a step graded layer) or without breaking vacuum of the previous process. In various examples, first superlattice structure 206 may be carbon doped using an extrinsic carbon source to control an amount of carbon flowing to control the concentration of carbon in first superlattice structure 206.

Referring now to FIG. 2C, and continuing with step 104 of FIG. 1, a second superlattice structure 208 is formed over first superlattice structure 206. At this point in method 100, III-N buffer layer 219 now includes base layer 204, first superlattice structure 206, and second superlattice structure 208. Furthermore, in various examples, voltage sustaining partition 219a of the III-N buffer layer 219 now includes first superlattice structure 206 and second superlattice structure 208. In various examples, second superlattice structure 208 includes alternating pairs of a third III-N material layer 208a and a fourth III-N material layer 208b. That is, second superlattice structure 208 includes a plurality of alternating pairs of third III-N material layer 208a and fourth III-N material layer 208b similar to that shown in FIG. 2B and described above with respect to first superlattice structure 206.

Each third III-N material layer 208a includes one or more elements such as a III-N material doped with carbon. In various examples, the one or more elements may be similar to those described above with respect to first III-N material layer 206a in FIG. 2A. In various examples, third III-N material layer 208a may include carbon doped aluminum nitride (AlN:C). Additionally, each layer of third III-N material layer 208a may have a third thickness and a third group III element concentration. In various examples, the third thickness may be about 2 nm to about 8 nm, and more specifically, about 4 nm to about 6 nm. In various examples, the third group III element may be aluminum (e.g., AlN:C) and the aluminum concentration may be about 90% to about 100%.

Each fourth III-N material layer 208b in second superlattice structure 208 includes one or more elements similar to second III-N material layer 206b described above in FIG. 2A. In various examples, fourth III-N material layer 208b has a different material composition than third III-N material layer 208a. In various examples, fourth III-N material layer 208b may include carbon doped aluminum gallium nitride (AlGaN:C).

In various examples, fourth III-N material layer 208b has a fourth thickness and a fourth group III element concentration. In various examples, the fourth thickness may be about 15 nm to about 25 nm, and more specifically, about 17 nm to about 23 nm. In various examples, the fourth group III element may be aluminum (e.g., AlGaN:C) and the aluminum concentration may be about 25% to about 35%, and more specifically, about 27% to about 31% (e.g., Al_{0.29}Ga_{0.71}N:C).

Because of the plurality of pairs of third III-N material layer 208a and fourth III-N material layer 208b, second superlattice structure 208 has a second superlattice thickness. In various examples, the second superlattice thickness may be about 700 nm to about 3,000 nm, and more specifically, about 900 nm to about 2,550 nm, depending on the designed voltage breakdown and the number of processing loops (e.g., cycles, pairs of layers) performed to form second superlattice structure 208. In various examples, the cyclical process may be repeated about 28 times to about 120 times, and more specifically, about 36 times to about 102 times. In various examples, the first superlattice thickness may be based on the desired (or designed) breakdown voltage of device 200. In some examples, when device 200 has a lower voltage rating (e.g., 100 V), the second superlattice thickness may be about 700 nm to about 1,100 nm, and more specifically, about 800 nm to about 1,000 nm. In some other examples, when device 200 has a higher voltage rating (e.g., 650 V), the second superlattice thickness may be about 2,500 nm to about 3,000 nm, and more specifically, about 2,650 nm to about 2,850 nm. In further examples, when device 200 has an even higher voltage rating (e.g., 1,200 V), the second superlattice thickness may be about 2,300 nm to about 2,800 nm, and more specifically, about 2,450 nm to about 2,650 nm.

In various examples, such as when device 200 includes first superlattice structure 206, the second superlattice thickness may be greater than the first superlattice thickness. For example, a ratio of thickness of the first superlattice thickness to the second superlattice thickness may be about 3.5:1 to about 15:1. In various examples, increasing the thickness of second superlattice structure 208, relative to first superlattice structure 206, helps manage strain within the device 200.

In various examples, the group III element concentration of second superlattice structure 208 maybe be a weighted average of the group III element across all of third III-N material layers 208a and fourth III-N material layers 208b forming second superlattice structure 208. That is, the weighted average accounts for the respective thicknesses and group III element concentrations of third III-N material layer 208a and fourth III-N material layer 208b. Therefore, in some examples, the thicker fourth III-N material layer 208b having a lower group III element concentration has a greater effect on the average group III element concentration than the thinner third III-N material layer 208a having a higher group III element concentration. In various examples, when the group III element is aluminum in both the third III-N material layers 208a and fourth III-N material layers 208b the weighted average of aluminum concentration of second superlattice structure 208 may be about 35% to about 50%, and more specifically, about 40% to about 45%.

In various examples, the carbon concentration of second superlattice structure 208 may be (e.g., vary between) about 1×10¹⁷ cm⁻³ to about 5×10¹⁹ cm⁻³, and more specifically, about 5×10¹⁷ cm⁻³ to about 1×10¹⁹ cm⁻³. In various examples, second superlattice structure 208 may have a carbon concentration equal to or greater than a carbon concentration of first superlattice structure 206. In various examples, second superlattice structure 208 may be in situ carbon doped during one or more epitaxial growth processes. In various examples, second superlattice structure 208 may be carbon doped using an extrinsic carbon source to control an amount of carbon flowing to control the concentration of carbon in second superlattice structure 208.

Referring now to FIG. 2D, and continuing with step 104 of FIG. 1, a third superlattice structure 210 is formed over second superlattice structure 208. At this point in method 100, III-N buffer layer 219 now includes base layer 204, first superlattice structure 206, second superlattice structure 208, and third superlattice structure 210. Furthermore, in various examples, voltage sustaining partition 219a of the III-N buffer layer 219 now includes first superlattice structure 206, second superlattice structure 208, and third superlattice structure 210. In various examples, third superlattice structure 210 includes alternating pairs of a fifth III-N material layer 210a and a sixth III-N material layer 210b. That is, third superlattice structure 210 includes a plurality of alternating pairs of fifth III-N material layer 210a and sixth III-N material layer 210b similar to that shown in FIG. 2B and described above with respect to first superlattice structure 206.

Each fifth III-N material layer 210a includes one or more elements such as a III-N material doped with carbon. In various examples, the one or more elements may be similar to those described above with respect to first III-N material layer 206a in FIG. 2A. In various examples, fifth III-N material layer 210a may include carbon doped aluminum nitride (AlN:C). Additionally, each layer of fifth III-N material layer 210a may have a fifth thickness and a fifth group III element concentration. In various examples, the fifth thickness may be about 2 nm to about 8 nm, and more specifically, about 4 nm to about 6 nm. In various examples, the fifth group III element may be aluminum (e.g., AlN:C) and the aluminum concentration may be about 90% to about 100%.

Each sixth III-N material layer 210b in third superlattice structure 210 includes one or more elements similar to second III-N material layer 206b described above in FIG. 2A. In various examples, sixth III-N material layer 210b has a different material composition than fifth III-N material layer 210a. In various examples, sixth III-N material layer 210b may include carbon doped aluminum gallium nitride (AlGaN:C).

In various examples, sixth III-N material layer 210b has a sixth thickness and a sixth group III element concentration. In various examples, the sixth thickness may be about 15 nm to about 25 nm, and more specifically, about 17 nm to about 23 nm. In various examples, the sixth group III element may be aluminum (e.g., AlGaN:C) and the aluminum concentration may be about 17% to about 27%, and more specifically, about 20% to about 24% (e.g., Al_{0.22}Ga_{0.78}N:C).

Because of the plurality of pairs of fifth III-N material layer 210a and sixth III-N material layer 210b, third superlattice structure 210 has a third superlattice thickness. In various examples, the third superlattice thickness may be about 200 nm to about 400 nm, and more specifically, about 250 nm to about 350 nm, depending on the designed voltage breakdown and the number of processing loops (e.g., cycles, pairs of layers) performed to form third superlattice structure 210. In various examples, the cyclical process may be repeated about 8 times to about 16 times, and more specifically, about 10 times to about 14 times. In various examples, the third superlattice thickness may be based on the desired (or designed) breakdown voltage of device 200. For example, the third superlattice thickness as described above may be used when device 200 has a higher voltage rating (e.g., 1,200 V). In other examples, when device 200 has a lower voltage rating (e.g., 100 V or 650 V) third superlattice structure 210 may be omitted, as described in more detail below in FIG. 2J.

In various examples, such as when device 200 includes third superlattice structure 210, the third superlattice thickness may be less than second super lattice thickness and about equal to the first superlattice thickness. In various examples, a ratio of a thickness of the third superlattice thickness to the second superlattice thickness may be about 3.5:1 to about 15:1. In various examples, decreasing the thickness of third superlattice structure 210, relative to second superlattice structure 208, helps manage strain within the device 200.

In various examples, the group III element concentration of third superlattice structure 210 maybe be a weighted average of the group III element across all of fifth III-N material layers 210a and sixth III-N material layers 210b forming third superlattice structure 210. That is, the weighted average accounts for the respective thicknesses and group III element concentrations of fifth III-N material layer 210a and sixth III-N material layer 210b. Therefore, in some examples, the thicker sixth III-N material layer 210b having a lower group III element concentration has a greater effect on the average group III element concentration than the thinner fifth III-N material layer 210a having a higher group III element concentration. In various examples, when the group III element is aluminum in both the fifth III-N material layers 210a and sixth III-N material layers 210b the weighted average of aluminum concentration of third superlattice structure 210 may be about 30% to about 45%, and more specifically, about 35% to about 40%.

In various examples, the carbon concentration of third superlattice structure 210 may be (e.g., vary between) about 1×10¹⁷ cm⁻³ to about 5×10¹⁹ cm⁻³, and more specifically, about 5×10¹⁷ cm⁻³ to about 1×10¹⁹ cm⁻³. In various examples, third superlattice structure 210 may have a carbon concentration equal to or greater than a carbon concentration of first superlattice structure 206 and/or second superlattice structure 208. In various examples, third superlattice structure 210 may be in situ carbon doped during one or more epitaxial growth processes. In various examples, third superlattice structure 210 may be carbon doped using an extrinsic carbon source to control an amount of carbon flowing to control the concentration of carbon in third superlattice structure 210.

Referring now to FIG. 2E, and continuing with step 104 of FIG. 1, a fourth superlattice structure 212 is formed over third superlattice structure 210. At this point in method 100, III-N buffer layer 219 now includes base layer 204, first superlattice structure 206, second superlattice structure 208, third superlattice structure 210, and fourth superlattice structure 212. Furthermore, in various examples, voltage sustaining partition 219a of the III-N buffer layer 219 now includes first superlattice structure 206, second superlattice structure 208, third superlattice structure 210, and fourth superlattice structure 212. In various examples, fourth superlattice structure 212 includes alternating pairs of a seventh III-N material layer 212a and an eighth III-N material layer 212b. That is, fourth superlattice structure 212 includes a plurality of alternating pairs of seventh III-N material layer 212a and eighth III-N material layer 212b similar to that shown in FIG. 2B and described above with respect to first superlattice structure 206.

Each seventh III-N material layer 212a includes one or more elements such as a III-N material doped with carbon. In various examples, the one or more elements may be similar to those described above with respect to first III-N material layer 206a in FIG. 2A. In various examples, seventh III-N material layer 212a may include carbon doped aluminum nitride (AlN:C). Additionally, each layer of seventh III-N material layer 212a may have a seventh thickness and a seventh group III element concentration. In various examples, the seventh thickness may be about 2 nm to about 8 nm, and more specifically, about 4 nm to about 6 nm. In various examples, the seventh group III element may be aluminum (e.g., AlN:C) and the aluminum concentration may be about 90% to about 100%.

Each eighth III-N material layer 212b in third superlattice structure 210 includes one or more elements similar to second III-N material layer 206b described above in FIG. 2A. In various examples, eighth III-N material layer 212b has a different material composition than seventh III-N material layer 212a. In various examples, eighth III-N material layer 212b may include carbon doped aluminum gallium nitride (AlGaN:C).

In various examples, eighth III-N material layer 212b has an eighth thickness and an eighth group III element concentration. In various examples, the eighth thickness may be about 15 nm to about 25 nm, and more specifically, about 17 nm to about 23 nm. In various examples, the eighth group III element may be aluminum (e.g., AlGaN:C) and the aluminum concentration may be about 10% to about 20%, and more specifically, about 12% to about 18% (e.g., Al_{0.15}Ga_{0.85}N:C).

Because of the plurality of pairs of seventh III-N material layer 212a and eighth III-N material layer 212b, fourth superlattice structure 212 has a fourth superlattice thickness. In various examples, the fourth superlattice thickness may be about 100 nm to about 1,900 nm, and more specifically, about 200 nm to about 1,600 nm, depending on the designed voltage breakdown and the number of processing loops (e.g., cycles, pairs of layers) performed to form fourth superlattice structure 212. In various examples, the cyclical process may be repeated about 4 times to about 76 times, and more specifically, about 8 times to about 64 times. In some examples, when device 200 has a lower voltage rating (e.g., 100 V), the fourth superlattice thickness may be about 100 nm to about 300 nm, and more specifically, about 150 nm to about 250 nm. In some other examples, when device 200 has a higher voltage rating (e.g., 650 V), the fourth superlattice thickness may be about 1,100 nm to about 1,600 nm, and more specifically, about 1,250 nm to about 1,450 nm. In further examples, when device 200 has an even higher voltage rating (e.g., 1,200 V), the fourth superlattice thickness may be about 1,350 nm to about 1,850 nm, and more specifically, about 1,500 nm to about 1,700 nm.

In various examples, the fourth superlattice thickness may be greater than the first superlattice thickness and the third superlattice thickness and less than the second superlattice thickness. In various examples, a ratio of a thickness of the first superlattice thickness to the fourth superlattice thickness may be about 1:2 to about 9.5:1. In various examples, a ratio of a thickness of the fourth superlattice thickness to the second superlattice thickness may be about 3:1 to about 7:1. In various examples, decreasing the thickness of fourth superlattice structure 212, relative to second superlattice structure 208, helps manage strain within the device 200.

In various examples, the group III element concentration of fourth superlattice structure 212 maybe be a weighted average of the group III element across all of seventh III-N material layers 212a and eighth III-N material layers 212b forming fourth superlattice structure 212. That is, the weighted average accounts for the respective thicknesses and group III element concentrations of seventh III-N material layer 212a and eighth III-N material layer 212b. Therefore, in some examples, the thicker eighth III-N material layer 212b having a lower group III element concentration has a greater effect on the average group III element concentration than the thinner seventh III-N material layer 212a having a higher group III element concentration. In various examples, when the group III element is aluminum in both the seventh III-N material layers 212a and eighth III-N material layers 212b the weighted average of aluminum concentration of fourth superlattice structure 212 may be about 25% to about 40%, and more specifically, about 30% to about 35%.

In various examples, the carbon concentration of fourth superlattice structure 212 may be (e.g., vary between) about 1×10¹⁷ cm⁻³ to about 5×10¹⁹ cm⁻³, and more specifically, about 5×10¹⁷ cm⁻³ to about 1×10¹⁹ cm⁻³. In various examples, fourth superlattice structure 212 may have a carbon concentration equal to or greater than a carbon concentration of first superlattice structure 206, second superlattice structure 208, and/or third superlattice structure 210. In various examples, fourth superlattice structure 212 may be in situ carbon doped during one or more epitaxial growth processes. In various examples, fourth superlattice structure 212 may be carbon doped using an extrinsic carbon source to control an amount of carbon flowing to control the concentration of carbon in fourth superlattice structure 212.

Accordingly, the voltage-sustaining partition (e.g., first superlattice structure 206, second superlattice structure 208, third superlattice structure 210, and fourth superlattice structure 212), in its various examples, facilitates an increased breakdown voltage, or voltage rating, of device 200. The increased breakdown voltage of device 200 may be attributed to the thickness of the voltage-sustaining partition. Additionally, the thicknesses of first superlattice structure 206, second superlattice structure 208, third superlattice structure 210, and/or fourth superlattice structure 212, in their various examples, facilitate stress management of device 200, and more specifically, of III-N buffer layer 219. Additionally, the stress management may be attributed to the average aluminum concentration of first, second, third, and fourth superlattice structures 206, 208, 210, 212. As described above, the characteristics (e.g., thickness and/or average group III element concentration) of first, second, third, and fourth superlattice structures 206, 208, 210, 212 may be modified for use with devices (e.g., device 200) of varying voltages (e.g., about 100 V to about 1,200 V or greater). For example, higher voltage devices may be designed with relatively thicker superlattice structures (e.g., second superlattice structure 208 and fourth superlattice structure 212). The relatively thicker superlattice structures may have a relatively higher group III element (e.g., aluminum) average concentration. In contrast, lower voltage devices may be designed with a relatively thinner superlattice structures. The relatively thinner superlattice structures may have a relatively lower group III element (e.g., aluminum) average concentration.

Referring now to FIG. 2F, and continuing with step 104 of FIG. 1, a fifth superlattice structure 214 is formed over fourth superlattice structure 212. At this point in method 100, III-N buffer layer 219 now includes base layer 204, first superlattice structure 206, second superlattice structure 208, third superlattice structure 210, fourth superlattice structure 212, and fifth superlattice structure 214. Moreover, in various examples, back-barrier partition 219b of III-N buffer layer 219 now begins with the inclusion of fifth superlattice structure 214. In various examples, fifth superlattice structure 214 may be an optional layer within back-barrier partition 219b of III-N buffer layer 219. Fifth superlattice structure 214 includes alternating pairs of a ninth III-N material layer 214a and a tenth III-N material layer 214b. That is, fifth superlattice structure 214 includes a plurality of alternating pairs of the ninth III-N material layer 214a and tenth III-N material layer 214b similar to that shown in FIG. 2B and described above with respect to first superlattice structure 206.

Each ninth III-N material layer 214a includes one or more elements, such as a III-N material doped with carbon. In various examples, the one or more elements may be similar to those describe above with respect to first III-N material layer 206a in FIG. 2A. In various examples, ninth III-N material layer 214a may include carbon doped aluminum nitride (AlN:C).

In various examples, each layer of ninth III-N material layer 214a has a ninth thickness and a ninth group III element concentration. In various examples, the ninth thickness may be about 2 nm to about 8 nm, and more specifically, about 4 nm to about 6 nm. In various examples, the ninth group III element may be aluminum (e.g., AlN:C) and the aluminum concentration may be about 90% to about 100%.

Each tenth III-N material layer 214b in fifth superlattice structure 214 includes one or more elements that may be similar to second III-N material layer 206b described above in FIG. 2A. In various examples, tenth III-N material layer 214b has a different material composition than ninth III-N material layer 214a. In various examples, tenth III-N material layer 214b may include carbon doped aluminum gallium nitride (AlGaN:C).

In various examples, tenth III-N material layer 214b has a tenth thickness and a tenth group III element concentration. In various examples, the tenth thickness may be about 15 nm to about 25 nm, and more specifically, about 17 nm to about 23 nm. In various examples, the tenth group III element may be aluminum (e.g., AlGaN:C) and the aluminum concentration may be about 10% to about 20%, and more specifically, about 12% to about 18% (e.g., Al_{0.15}Ga_{0.85}N:C).

Because of the plurality of pairs of ninth III-N material layer 214a and tenth III-N material layer 214b, fifth superlattice structure 214 has a fifth superlattice thickness. In various examples, the fifth superlattice thickness may be about 75 nm to about 525 nm, and more specifically, about 150 nm to about 450 nm, depending on the design and the number of processing loops (e.g., cycles, pairs of layers) performed to form fifth superlattice structure 214. In various examples, the cyclical process may be repeated about 3 times to about 21 times, and more specifically, about 6 times to about 18 times. In some examples when device 200 has a lower voltage rating (e.g., 100 V), the fifth superlattice thickness may be about 75 nm to about 225 nm, and more specifically, about 125 nm to about 175 nm. In some other examples when device 200 has a higher voltage rating (e.g., 650 V, 1,200 V), the fifth superlattice thickness may be about 375 nm to about 525 nm, and more specifically, about 425 nm to about 475 nm.

In various examples, fifth superlattice thickness may be less than fourth superlattice thickness. In various examples, a ratio of a thickness of the fifth superlattice thickness to the fourth superlattice thickness may be about 1:1 to about 3.5:1. In various examples, decreasing the thickness of fifth superlattice structure 214, relative to fourth superlattice structure 212, helps manage strain within the device 200.

In various examples, the group III element concentration of fifth superlattice structure 214 maybe be a weighted average of the group III element across ninth III-N material layers 214a and tenth III-N material layers 214b forming fifth superlattice structure 214. That is, the weighted average accounts for the respective thicknesses and group III element concentrations of ninth III-N material layer 214a and tenth III-N material layer 214b. Therefore, in some examples, the thicker tenth III-N material layer 214b having a lower group III element concentration has a greater effect on the average group III element concentration than the thinner ninth III-N material layer 214a having a higher group III element concentration. In various examples, when the group III element is aluminum in both the ninth III-N material layers 214a and tenth III-N material layers 213b the weighted average of aluminum concentration of fifth superlattice structure 214 may be about 25% to about 40%, and more specifically, about 30% to about 35%. In some examples, the group III element concentration of fifth superlattice structure 214 is equal to or less than the group III element concentration of fourth superlattice structure 212.

In various examples, the carbon concentration of fifth superlattice structure 214 may be (e.g., vary between) about 1×10¹⁹ cm⁻³ to about 1×10²² cm⁻³, and more specifically, about 5×10¹⁹ cm⁻³ to about 5×10²¹ cm⁻³. That is, in some examples, the carbon concentration of fifth superlattice structure 214 may be greater than the carbon concentration of fourth superlattice structure 212. In various examples, the carbon concentration of fifth superlattice structure 214 may be about two orders of magnitude greater than the carbon concentration of fourth superlattice structure 212. In various examples, fifth superlattice structure 214 may be in situ carbon doped during one or more epitaxial growth processes. In various examples, fifth superlattice structure 214 may be carbon doped using an extrinsic carbon source to control an amount of carbon flowing to control the concentration of carbon in fifth superlattice structure 214.

Fifth superlattice structure 214, in its various examples, facilitates decreased current collapse of device 200. The reduced current collapse may be attributed to increased carbon concentration of fifth superlattice structure 214 (e.g., in comparison to carbon concentration of fourth superlattice structure 212 or in comparison to carbon concentration of the voltage sustaining partition). Accordingly, in various examples, fifth superlattice structure 214 may be considered as being part of back-barrier partition 219b of III-N buffer layer 219. Additionally, fifth superlattice structure 214, in its various examples, may facilitate stress management of device 200, and more specifically III-N buffer layer 219. The stress management may be attributed to the average aluminum concentration of fifth superlattice structure 214. As described above, the characteristics (e.g., average group III element concentration and/or carbon concentration) of fifth superlattice structure 214 may be modified for use with devices (e.g., device 200) of varying voltages (e.g., about 100 V to about 1,200 V). For example, higher voltage devices may be designed with fifth superlattice structure 214 having a relatively higher carbon concentration while lower voltage devices may be designed with a relatively lower carbon concentration for fifth superlattice structure 214.

Referring now to FIG. 2G, and continuing with step 104 of FIG. 1, a sixth superlattice structure 216 is formed over fifth superlattice structure 214. At this point in method 100, III-N buffer layer 219 now includes base layer 204, first superlattice structure 206, second superlattice structure 208, third superlattice structure 210, fourth superlattice structure 212, fifth superlattice structure 214, and sixth superlattice structure 216. Moreover, in various examples, back-barrier partition 219b of III-N buffer layer 219 now includes fifth superlattice structure 214 and sixth superlattice structure 216. Sixth superlattice structure 216 includes a plurality of alternating pairs of an eleventh III-N material layer 216a and a twelfth III-N material layer 216b. That is, sixth superlattice structure 216 includes a plurality of alternating pairs of eleventh III-N material layer 216a and twelfth III-N material layer 216b similar to that shown in FIG. 2B and described above with respect to first superlattice structure 206.

Each eleventh III-N material layer 216a in sixth superlattice structure 216 includes one or more elements such as III-N materials doped with carbon. In various examples, the one or more elements may be similar to those describe above with respect to first III-N material layer 206a in FIG. 2A. In various examples, eleventh III-N material layer 216a may include carbon doped aluminum nitride (AlN:C).

In various examples, each layer of eleventh III-N material layer 216a has an eleventh thickness and an eleventh group III element concentration. In various examples, the eleventh thickness may be about 0.5 nm to about 2.5 nm, and more specifically, about 1 nm to about 2 nm. In various examples, the eleventh group III element may be aluminum (e.g., AlN:C) and the aluminum concentration may be about 90% to about 100%.

Each twelfth III-N material layer 216b in sixth superlattice structure 216 includes one or more elements, similar to second III-N material layer 206b described above in FIG. 2A. For example, twelfth III-N material layer 216b may include a carbon doped III-N material layer. In various examples, twelfth III-N material layer 216b may include carbon doped gallium nitride (GaN:C). In various examples, twelfth III-N material layer 216b has a different material composition than eleventh III-N material layer 216a.

In various examples, twelfth III-N material layer 216b has a twelfth thickness and a twelfth group III element concentration. In various examples, the twelfth thickness may be about 15 nm to about 30 nm, and more specifically, about 20 nm to about 25 nm. In various examples, the twelfth group III element may be gallium (e.g., GaN:C) such that the gallium concentration may be about 90% to about 100%. In examples, where twelfth III-N material layer 216b is formed of carbon doped gallium nitride (GaN:C) the aluminum concentration may be 0%.

Because of the plurality of pairs of eleventh III-N material layer 216a and twelfth III-N material layer 216b, sixth superlattice structure 216 has a sixth superlattice thickness. In various examples, the sixth superlattice thickness may be about 50 nm to about 300 nm, and more specifically, about 100 nm to about 250 nm, depending on the number of processing loops (e.g., cycles, pairs of layers) performed to form sixth superlattice structure 216. In various examples, the cyclical process may be repeated about 2 times to about 14 times, and more specifically, about 4 times to about 10 times. In some examples, when device 200 has a lower voltage rating (e.g., 100 V), the sixth superlattice thickness may be about 50 nm to about 150 nm, and more specifically, about 75 nm to about 125 nm. In some other examples, when device 200 has a higher voltage rating (e.g., 650 V, 1,200 V), the sixth superlattice thickness may be about 200 nm to about 300 nm, and more specifically, about 225 nm to about 275 nm. In various examples, the sixth superlattice thickness is less than the fifth superlattice thickness. In various examples, decreasing the thickness of sixth superlattice structure 216, relative to first, second, third, fourth, and/or fifth superlattice structures 206, 208, 210, 212, 214, helps manage strain within the device 200.

In various examples, the group III element concentration of sixth superlattice structure 216 maybe be a weighted average of the group III element across all of eleventh III-N material layers 216a and twelfth III-N material layers 216b forming sixth superlattice structure 216. That is, the weighted average accounts for the respective thicknesses and group III element concentrations of eleventh III-N material layer 216a and twelfth III-N material layer 216b. Therefore, in some examples, the thicker twelfth III-N material layer 216b having a lower group III element concentration has a greater effect on the average group III element concentration than the thinner eleventh III-N material layer 216a having a higher group III element concentration. In various other examples, when eleventh III-N material layer 216a is carbon doped aluminum nitride (AlN:C) and twelfth III-N material layer 216b is carbon doped gallium nitride (GaN:C), the weighted average of the group III element (e.g., aluminum) is heavily influenced by eleventh III-N material layer 216a as twelfth III-N material layer 216b does not contain aluminum. In such examples, the weighted average of aluminum concentration of the combination of all of eleventh III-N material layers 216a and twelfth III-N material layers 216b in sixth superlattice structure 216 may be about 1% to about 10%, and more specifically, about 4% to about 8%.

In various examples, the carbon concentration of sixth superlattice structure 216 may be (e.g., vary between) about 1×10¹⁹ cm⁻³ to about 1×10²² cm⁻³, and more specifically, about 5×10¹⁹ cm⁻³ to about 5×10²¹ cm⁻³. That is in some examples, the carbon concentration of sixth superlattice structure 216 may be equal to or greater than the carbon concentration of fifth superlattice structure 214. In various examples, sixth superlattice structure 216 may be in situ carbon doped during one or more epitaxial growth processes. In various examples, sixth superlattice structure 216 may be carbon doped using an extrinsic carbon source to control an amount of carbon flowing to control the concentration of carbon in sixth superlattice structure 216.

Sixth superlattice structure 216, in its various examples, facilitates a decreased current collapse of device 200. This may be attributed to the carbon concentration of sixth superlattice structure 216. Accordingly, in various examples, sixth superlattice structure 216 may be considered as being part of back-barrier partition 219b of III-N buffer layer 219. As described above, the characteristics (e.g., carbon concentration) of sixth superlattice structure 216 may be modified for use with devices (e.g., device 200) of varying voltages (e.g., about 100 V to about 1,200 V). For example, higher voltage devices may be designed with sixth superlattice structure 216 having a relatively higher carbon concentration while lower voltage devices may be designed with a relatively lower carbon concentration for sixth superlattice structure 216.

Referring now to FIG. 2H, and continuing with step 104 of FIG. 1, a III-N layer (e.g., III-N back-barrier layer) 218 is formed over sixth superlattice structure 216. At this point in method 100, III-N buffer layer 219 now includes base layer 204, first superlattice structure 206, second superlattice structure 208, third superlattice structure 210, fourth superlattice structure 212, fifth superlattice structure 214, sixth superlattice structure 216, and III-N back-barrier layer 218. More specifically, in various examples, back-barrier partition 219b of III-N buffer layer 219 now includes fifth superlattice structure 214, sixth superlattice structure 216, and III-N back-barrier layer 218.

III-N back-barrier layer 218, in various examples, may include a III-N semiconductor material. In various examples, III-N back-barrier layer 218 may have a thickness of about 500 nm to about 2,500 nm, and more specifically, about 600 nm to about 2,100 nm. In some examples when device 200 has a lower voltage rating (e.g., 100 V), the thickness of III-N back-barrier layer 218 may be about 500 nm to about 700 nm, and more specifically, about 550 nm to about 650 nm. In some other examples when device 200 has a higher voltage rating (e.g., 650 V, 1,200 V), the thickness of III-N back-barrier layer 218 may be about 1,600 nm to about 2,500 nm, and more specifically, about 1,950 nm to about 2,150 nm.

In various examples, III-N back-barrier layer 218 may be or may include carbon doped gallium nitride (GaN:C). In some examples, III-N back-barrier layer 218 is free of (exclusive of) aluminum. In various examples, III-N back-barrier layer 218 may be extrinsically doped with carbon or other similar dopants. In some examples, III-N back-barrier layer 218 may have a carbon concentration that is the same as sixth superlattice structure 216. In other examples, III-N back-barrier layer 218 may have a different carbon concentration than sixth superlattice structure 216. That is, in some examples, III-N back-barrier layer 218 has a greater or lesser carbon concentration than sixth superlattice structure 216. In various examples, the carbon concentration of III-N back-barrier layer 218 may be (e.g., vary between) about 1×10¹⁹ cm⁻³ to about 1×10²² cm⁻³, and more specifically, about 5×10¹⁹ cm⁻³ to about 5×10²¹ cm⁻³.

After forming III-N back-barrier layer 218, III-N buffer layer 219 has a total thickness that may be about 2,070 nm to about 9,655 nm, and more specifically, about 2,775 nm to about 8,200 nm. In some examples when device 200 has a lower voltage rating (e.g., 100 V), the total thickness of III-N buffer layer 219 may be about 1,670 nm to about 2,920 nm, and more specifically, about 2,000 nm to about 2,590 nm. In some other examples when device 200 has a higher voltage rating (e.g., 650 V), the total thickness of III-N buffer layer 219 may be about 6,205 nm to about 8,555 nm, and more specifically, about 6,990 nm to about 7,770 nm. In further examples when device 200 has an even higher voltage rating (e.g., 1,200 V), the total thickness of III-N buffer layer 219 may be about 6,655 nm to about 9,455, and more specifically, about 7,540 nm to about 8,520 nm. III-N buffer layer 219, in its various examples, facilitates an increased breakdown voltage, or voltage rating, and decreased current collapse of device 200 while managing stresses caused by its thickness. These may be attributed to the decrease in aluminum concentration (e.g., average concentrations of aluminum in individual superlattice structures) and the increase in carbon concentration through III-N buffer layer 219 in a direction away from substrate 202. As described above, the characteristics (e.g., thickness, average group III element concentration, and/or carbon concentration) of III-N buffer layer 219 may be modified for use with devices (e.g., device 200) of varying voltages (e.g., about 100 V to about 1,200 V, or greater). Moreover, as described above, the partitioning of III-N buffer layer 219 into voltage sustaining partition 219a and back-barrier partition 219b allows for the decoupling of the enhancement of the breakdown voltage from the mitigation of current collapse while facilitating strain management in III-N buffer layers of high electron mobility devices (e.g., HEMT).

At step 106 of FIG. 1, active layers (which may also be referred to as device layers) of a high electron mobility device are formed over the III-N buffer layer. As shown in FIG. 2I, additional layers and structures, including active layers of a high electron mobility device (e.g., HEMT), are formed over III-N buffer layer 219, and more specifically, over III-N back-barrier layer 218. In various examples, the additional layers and structures may include a III-N channel layer 220, a barrier layer 222, a gate layer 228, a gate electrode 230, a passivation layer 232, a source-coupled field plate 234, including a source contact 234a in a source region 224, and a drain contact 236 in a drain region 226.

III-N channel layer 220 is formed over III-N buffer layer 219 and barrier layer 222 is formed over III-N channel layer 220. Gate layer 228 is formed over barrier layer 222 and gate electrode 230 is formed over gate layer 228 to form a gate stack 231 (e.g., gate structure). Passivation layer 232 is formed over barrier layer 222, gate layer 228, and gate electrode 230. Source-coupled field plate 234 is formed over barrier layer 222 and passivation layer 232. Source-coupled field plate 234 further includes a first portion 234a (which may also be referred to as a source contact 234a) formed in source region 224 and a second portion 234b formed over gate electrode 230. Drain contact 236 is formed over barrier layer 222 and passivation layer 232 in drain region 226. Source via 240 is formed over first portion 234a of source-coupled field plate 234 and drain via 242 is formed over drain contact 236. First metal line 244 is formed over source via 240 and second metal line 246 is formed over drain via 242.

III-N channel layer 220, in various examples, may be or may include a III-N semiconductor material. In various examples, III-N channel layer 220 may include aluminum (Al), gallium (Ga), nitrogen (N₂), or another element as described above. In various examples, III-N channel layer 220 includes a gallium nitride (GaN) layer and, in such examples, may be referred to as a GaN channel layer. In various examples, III-N channel layer 220 may be about 350 nm to about 460 nm. In various examples, III-N channel layer 220 is an undoped layer. In some examples, the material of III-N channel layer 220 is or includes an unintentionally doped material, such as a material doped by diffusion of dopants from another layer or low levels of carbon in view of the III-N channel layer 220 being grown using carbon based metalorganic materials—e.g., trimethylgallium (TMGa, Ga(CH₃)₃). In various examples, the concentration of dopant in the unintentionally doped material may not be detectable as such is considered an undoped layer. Accordingly, in various examples, III-N channel layer 220 may be referred to as an undoped layer or an unintentionally doped (UID) layer. In some examples, III-N channel layer 220 includes carbon concentration in the order of about 1×10¹⁵ cm⁻³ or about 1×10¹⁶ cm⁻³. In some examples, III-N channel layer 220 is free of (exclusive of) aluminum. In various examples, because of the unintentionally doped nature of III-N channel layer 220, the carbon concentration of III-N back-barrier layer 218 may be at least two orders of magnitude greater than the carbon concentration of III-N channel layer 220.

Barrier layer 222, in some examples, may be or may include an aluminum gallium nitride (AlGaN) layer and, in such examples, may be referred to as an AlGaN barrier layer (or a second III-N semiconductor layer). In some examples, the barrier layer 222 may be about 8 nm to 15 nm. In some examples, III-N channel layer 220 may be or may include indium aluminum gallium nitride (InᵢAlⱼGa₁₋ᵢ₋ⱼN) (where 0≤i≤1, 0≤j≤1, and 0≤i+j≤1), and barrier layer 222 may be or may include indium aluminum gallium nitride (InₖAlₗGa₁₋ₖ₋ₗN) (where 0≤k≤1, 0≤l≤1, and 0≤k+l≤1). Other materials may be implemented for III-N channel layer 220 and/or barrier layer 222.

III-N channel layer 220 is configured, in conjunction with barrier layer 222, to conduct and confine charge carriers (such as electrons) within two dimensions. That is, charge carriers can be induced proximate to an interface of such a heterojunction structure having two dissimilar semiconductor materials in contact with each other (e.g., the III-N channel layer 220 and the barrier layer 222). In some examples, III-N channel layer 220 and barrier layer 222 may collectively be referred to as a III-N heterojunction structure (e.g., GaN heterojunction structure). In various examples, the charge carriers are induced at or near the surface of III-N channel layer 220, which is in contact with barrier layer 222, at least partially due to conduction-band offset between the two semiconductor materials (e.g., GaN and AlGaN). Moreover, the charge carriers may be induced by polarization discontinuity present in the III-N heterojunction structure. Such a layer of highly mobile electrons may be referred to as a 2-dimensional electron gas (2DEG) 221, a 2DEG layer, or charge carriers as denoted in FIG. 2G.

Gate layer 228 may then be formed over barrier layer 222. In some examples, gate layer 228 is or includes a III-N semiconductor material to form a III-N semiconductor material layer. Further, in some examples, gate layer 228 is doped with a dopant. In some examples, gate layer 228 is doped with a p-type dopant. Accordingly, gate layer 228 may also be referred to as a p-type III-N semiconductor material. In some examples, gate layer 228 may be or include a gallium nitride (GaN) layer, such as indium aluminum gallium nitride (InₘAlₙGa₁₋ₘ₋ₙN) (where 0≤m<1, 0≤n<1, and 0≤m+n≤1), and the dopant with which gate layer 228 is doped is a p-type dopant, which may be or include magnesium (Mg), carbon (C), zinc (Zn), the like, or a combination thereof. In examples in which gate layer 228 is gallium nitride (GaN) doped with a p-type dopant, gate layer 228 may be referred to as a p-doped GaN (pGaN) layer. Further, in examples in which gate layer 228 is gallium nitride (GaN) doped with a magnesium, gate layer 228 may be referred to as a magnesium doped gallium nitride (GaN:Mg) layer. In some examples, a concentration of the dopant in gate layer 228, which is electrically activated, is equal to or greater than 1×10¹⁷ cm⁻³. In some examples, the concentration is equal to or greater than 1×10¹⁸ cm⁻³. In some examples, the dopant in gate layer 228 may have a uniform concentration. In some examples, the dopant in gate layer 228 may have a gradient concentration. Other materials, dopants, and/or concentrations may be implemented in other examples.

In some examples, III-N buffer layer 219, III-N channel layer 220, barrier layer 222, and gate layer 228 may be formed by using any appropriate deposition process. In various examples, the deposition process may include an epitaxial growth process. For example, III-N buffer layer 219, III-N channel layer 220, barrier layer 222, and gate layer 228 may each be epitaxially grown using metal-organic chemical vapor deposition (MOCVD), molecular beam epitaxy (MBE), low pressure chemical vapor deposition (LPCVD), and/or another epitaxy process. In some examples, III-N buffer layer 219 may be in situ doped during deposition (e.g., epitaxial growth) —e.g., by using an external doping source. In some examples, gate layer 228 may be doped in situ during deposition (e.g., epitaxial growth) or by implantation (e.g., ion implantation) subsequent to deposition.

Gate electrode 230, in various examples, may be formed using one or more deposition processes, such as sputtering, physical vapor deposition (PVD), chemical vapor deposition (CVD), or the like, or any combination thereof. In various examples, gate electrode 230 may include titanium, nickel, titanium nitride, titanium tungsten, tungsten, or a combination thereof. Other metals for gate electrode 230 are within the scope of this disclosure such that gate electrode 230 may include or be any appropriate metal and/or metal alloy.

In some examples, gate electrode 230 may form a Schottky junction with gate layer 228. As examples, when the gate layer 228 is magnesium doped gallium nitride (GaN:Mg), metal that may form a Schottky junction with gate layer 228 may be or include titanium (Ti), titanium tungsten (TiW), titanium nitride (TiN), nickel (Ni), platinum (Pt), tantalum nitride (TaN), copper (Cu), tungsten (W), or alloys thereof. In some examples, gate electrode 230 may form an ohmic junction with gate layer 228. As examples, when gate layer 228 is magnesium doped gallium nitride (GaN:Mg), metal that may form an ohmic junction with gate layer 228 may be or include gold (Au), nickel (Ni), aluminum (Al), or alloys thereof, which alloys may include titanium tungsten aluminum (TiWAl) and titanium aluminum nitride (TiAlN). In some examples, gate electrode 230 includes a first portion including a metal that forms a Schottky junction with gate layer 228 and a second portion including a metal that forms an ohmic junction with gate layer 228, such as described in U.S. patent application Ser. No. 18/361,997, filed Jul. 31, 2023, which is incorporated by reference herein in its entirety.

Passivation layer 232 (e.g., a dielectric layer) is then formed over barrier layer 222 and gate stack 231, and more specifically, over gate electrode 230. As shown, passivation layer 232 may be formed (e.g., conformally formed) over, on, and along the sidewalls and an upper surface of gate stack 231, including gate layer 228 and gate electrode 230. In some examples, passivation layer 232 may be or include silicon nitride, silicon oxide, silicon oxynitride, aluminum oxide (Al₂O₃), aluminum nitride (AlN), aluminum oxynitride (AlON), hafnium oxide (HfO₂), any other dielectric material, or a combination thereof. Passivation layer 232 may be formed by one or more low pressure chemical vapor deposition (LPCVD) processes, plasma enhanced chemical vapor deposition (PECVD) processes, high density plasma (HDP) processes, or atomic layer deposition (ALD) processes, by way of example.

Additionally, as shown, device 200 further includes source region 224 and drain region 226. A channel region extends laterally between source region 224 and drain region 226 and within III-N channel layer 220. More specifically, the channel region underlies gate stack 231 (e.g., a gate structure) in gate region 233. Within high electron mobility devices, such as device 200, charge carriers (e.g., electrons in two-dimensional electron gas (2DEG) 221) are formed in III-N channel layer 220. For example, the charge carriers are formed in III-N channel layer 220 proximate to the surface of III-N channel layer 220 that is in contact with barrier layer 222. This provides a channel for current conduction (e.g., within III-N channel layer 220) between source region 224 and drain region 226. As such, the channel region between source region 224 and drain region 226 may be referred to as a surface channel, a device channel, or a transistor channel. Moreover, gate stack 231 is positioned in gate region 233 between source region 224 and drain region 226 to control the current conduction through III-N channel layer 220.

Source-coupled field plate 234 and drain contact 236, in various examples, may be a metal or metal alloy among other conductive materials. In various examples, the metal and/or metal alloy may include aluminum (Al), cobalt (Co), silicon chromium (SiCr), and/or silicon carbide chromium (SiCCr). In various examples, the metal and/or metal alloy may include titanium nitride (TiN), tantalum nitride (TaN), titanium (Ti), aluminum (Al), copper (Cu), tungsten (W), the like, or a combination thereof. Source-coupled field plate 234 and drain contact 236 may be deposited using a physical vapor deposition (PVD) deposition method or other suitable process techniques. Source-coupled field plate 234 and/or drain contact 236 may be a single material layer or may include multiple layers of a same material composition. In various examples, the metal or metal alloy may be formed and then etched to form source-coupled field plate 234 and drain contact 236.

Source-coupled field plate 234 includes first portion 234a (which may also be referred to as source contact) and second portion 234b (e.g., etch stop, field plate). First portion 234a operates as a contact to the high electron mobility device and is conductively coupled to source region 224. Second portion 234b may operate as an etch stop and as a field plate for device 200. As a field plate, second portion 234b operates to reduce the maximum electric field, increase the breakdown voltage of semiconductor devices, and/or achieve a desirable electrical field profile across the channel, among other functions. As an etch stop, second portion 234b operates to cover gate stack 231 and laterally extend from the gate stack 231 to protect gate stack 231 during processing of device 200.

At step 108 of FIG. 1, additional process steps are performed. Continuing with FIG. 2G, device 200 includes a dielectric layer 238, a source via 240, a drain via 242, a first metal line 244, and a second metal line 246. Dielectric layer 238 (e.g., interlayer dielectric (ILD) layer) is formed over passivation layer 232, source-coupled field plate 234, and drain contact 236. In various examples, dielectric layer 238 may be a single dielectric layer or may include multiple dielectric layers of a same dielectric material or different dielectric materials. In various examples, dielectric layer 238 may include silicon nitride, a silicon oxide-based material (such as a phosphosilicate glass (PSG) or a tetraethyl orthosilicate (TEOS) oxide), polytetrafluoroethylene, or the like.

Source via 240 and drain via 242 are formed through dielectric layer 238 and connect to first portion 234a of source-coupled field plate and drain contact 236, respectively. The metal vias may each include (i) one or more metal-barrier and/or adhesion layers (e.g., titanium nitride (TiN), tantalum nitride (TaN), the like, or a combination thereof) conformally in a respective opening through the ILD layer and (ii) a fill metal (e.g., aluminum (Al), copper (Cu), tungsten (W), the like, or a combination thereof) over and/or on the metal-barrier and/or adhesion layer(s). Also, one or more metal lines may be formed over and on (and electrically connected to) the metal vias.

First metal line 244 and second metal line 246 are formed over source via 240 and drain via 242, respectively. First metal line 244 and second metal line 246 may each include a metal and/or a metal layer including, for example, titanium nitride (TiN), tantalum nitride (TaN), aluminum (Al), copper (Cu), the like, or a combination thereof.

Although device 200 is described and shown as being an E-mode HEMT, the present disclosure is not limited to this implementation. For example, as described above, it is understood that the methods and structures disclosed herein are applicable to any high electron mobility device including both E-mode HEMTs and D-mode HEMTs. That is, the improved III-N buffer layer (e.g., III-N buffer layer 219), including the increasing carbon dopant concentration in a direction towards the active layers of a high electron mobility device as described herein, can be included in any high electron mobility devices (including E-Mode and D-Mode HEMTs) independent of the presence of gate layer 228 in the gate stack. Moreover, in some examples, III-N devices other than HEMTs may be formed over the improved III-N buffer layer. For example, a III-N resistor may be formed over the improved III-N buffer layer. The III-N resistor may include various structures of device 200 except gate stack 231 and second portion 234b (e.g., etch stop, field plate) of source-coupled field plate 234.

In various examples, III-N buffer layer 219 may include fewer or more superlattice structures than first superlattice structure 206, second superlattice structure 208, third superlattice structure 210, fourth superlattice structure 212, fifth superlattice structure 214, and sixth superlattice structure 216 shown in FIGS. 2A-2I. That is, the number of layers (e.g., superlattice structures, step graded layers, etc.) within voltage sustaining partition 219a and/or back-barrier partition 219b of the III-N buffer layer 219 may be fewer or more than what is described above. In various examples, III-N buffer layer 219 may include three superlattice structures. For example, a first superlattice structure (e.g., second superlattice structure 208) formed over a semiconductor substrate (e.g., substrate 202), a second superlattice structure (e.g., third superlattice structure 210 or fourth superlattice structure 212) formed over the first superlattice structure, and a third superlattice structure (e.g., fifth superlattice structure 214 or sixth superlattice structure 216) formed over the second superlattice structure. That is, in some examples, III-N buffer layer 219 may be formed without one or more of the previously described superlattice structures.

In such examples where III-N buffer layer 219 is formed of three superlattice structures, the second superlattice structure may be thinner than the first superlattice structure and the third superlattice structure may be thinner than the second superlattice structure. Additionally, the carbon concentration in each superlattice structure may increase as compared to an adjacent superlattice structure in a direction away from substrate 202. In various examples, the average aluminum concentration in each superlattice structure may decrease as compared to an adjacent superlattice structure in a direction away from substrate 202.

In various examples, voltage sustaining partition 219a may include a first superlattice structure (e.g., second superlattice structure 208) while back-barrier partition 219b may include a second superlattice structure (e.g., fifth superlattice structure 214) and a third superlattice structure (e.g., sixth superlattice structure 216). In various examples, voltage sustaining partition 219a may include a first superlattice structure (e.g., second superlattice structure 208) and a second superlattice structure (e.g., fourth superlattice structure 212) while back-barrier partition 219b may include a third superlattice structure (e.g., sixth superlattice structure 216). Therefore, the breakdown voltage enhancement and the current collapse mitigation may be achieved by the two partitions in III-N buffer layer 219 having fewer than six superlattice structures. Furthermore, voltage sustaining partition 219a and back-barrier partition 219b are independent, or decoupled, from one another. Each partition may be optimized without affecting or relying on the other partition.

Referring now to FIG. 2J, a device 200′ is shown including III-N buffer layer 219 that is formed of four superlattice structures. As described above with respect to device 200, in various examples when the voltage rating of device 200 is lower (e.g., 100 V, 650 V), first superlattice structure 206 and third superlattice structure 210 may be omitted. Accordingly, device 200′ is shown in FIG. 2J with III-N buffer layer 219 being formed of base layer 204, second superlattice structure 208, fourth superlattice structure 212, fifth superlattice structure 214, sixth superlattice structure 216, and III-N back-barrier layer 218. More specifically, voltage sustaining partition 219a includes second superlattice structure 208 and fourth superlattice structure 212 and back-barrier partition 219b includes fifth superlattice structure 214, sixth superlattice structure 216, and III-N back-barrier layer 218. As described above and in various examples, the second superlattice thickness may be greater than the fourth superlattice thickness and the fourth superlattice thickness may be greater than the fifth superlattice thickness and/or the sixth superlattice thickness.

Additionally, as described above and in various examples, the carbon concentration of fourth superlattice structure 212 may be greater than or equal to the carbon concentration of second superlattice structure 208 and the carbon concentration of sixth superlattice structure 216 may be greater than or equal to the carbon concentration of fifth superlattice structure 214. Moreover, the carbon concentration of fifth superlattice structure 214 may be about two orders of magnitude greater than the carbon concentration of fourth superlattice structure 212.

Therefore, the breakdown voltage enhancement and the current collapse mitigation may be achieved by the two partitions in III-N buffer layer 219 having fewer than six superlattice structures. Furthermore, voltage sustaining partition 219a and back-barrier partition 219b are independent, or decoupled, from one another. Each partition may be optimized without affecting or relying on the other partition.

Referring now to FIG. 2K, a device 270 is shown including III-N buffer layer 219 that is formed having four step graded layers. Specifically, voltage sustaining partition 219a of III-N buffer layer 219 may be formed of a first step graded layer 272, a second step graded layer 274, a third step graded layer 276, and a fourth step graded layer 278 while back-barrier partition 219b of III-N buffer layer 219 may be formed of fifth superlattice structure 214, sixth superlattice structure 216, and III-N back-barrier layer 218. Each of first, second, third, and fourth step graded layers 272, 274, 276, 278 may include multiple III-N material layers (e.g., AlₓGa₁₋ₓN layer), in which individual III-N material layers have respective concentrations (compositions) of a group III element (e.g., aluminum) different from each other such that a concentration profile (e.g., aluminum concentration profile) throughout the step graded layers of III-N materials resembles a stairstep shape.

In various examples, first step graded layer 272 may have a similar average aluminum concentration, carbon concentration, and/or thickness as first superlattice structure 206. For example, the average aluminum concentration of first step graded layer 272 may be about 40% to about 55%, and more specifically, about 45% to about 50%. The thickness of first step graded layer 272 may be about 200 nm to about 400 nm, and more specifically, about 250 nm to about 350 nm, depending on the voltage rating of device 270 (as described above with reference to first superlattice structure 206). The carbon concentration of first step graded layer 272 may be (e.g., vary between) about 1×10¹⁷ cm⁻³ to about 5×10¹⁹ cm⁻³, and more specifically, about 5×10¹⁷ cm⁻³ to about 1×10¹⁹ cm⁻³.

In various examples, second step graded layer 274 may have a similar average aluminum concentration, carbon concentration, and/or thickness as second superlattice structure 208. For example, the average aluminum concentration of second step graded layer 274 may be about 35% to about 50%, and more specifically, about 40% to about 45%. The thickness of second step graded layer 274 may be about 700 nm to about 3,000 nm, and more specifically, about 900 nm to about 2,550 nm, depending on the voltage rating of device 270 (as described above with reference to second superlattice structure 208). The carbon concentration of second step graded layer 274 may be (e.g., vary between) about 1×10¹⁷ cm⁻³ to about 5×10¹⁹ cm⁻³, and more specifically, about 5×10¹⁷ cm⁻³ to about 1×10¹⁹ cm⁻³.

In various examples, third step graded layer 276 may have a similar average aluminum concentration, carbon concentration, and/or thickness as third superlattice structure 210. For example, the average aluminum concentration of third step graded layer 276 may be about 30% to about 45%, and more specifically, about 35% to about 40%. The thickness of third step graded layer 276 may be about 200 nm to about 400 nm, and more specifically, about 250 nm to about 350 nm, depending on the voltage rating of device 270 (as described above with reference to third superlattice structure 210). The carbon concentration of third step graded layer 276 may be (e.g., vary between) about 1×10¹⁷ cm⁻³ to about 5×10¹⁹ cm⁻³, and more specifically, about 5×10¹⁷ cm⁻³ to about 1×10¹⁹ cm⁻³.

In various examples, fourth step graded layer 278 may have a similar average aluminum concentration, carbon concentration, and/or thickness as fourth superlattice structure 212. For example, the average aluminum concentration of fourth step graded layer 278 may be about 25% to about 40%, and more specifically, about 30% to about 35%. The thickness of fourth step graded layer 278 may be about 100 nm to about 1,900 nm, and more specifically, about 200 nm to about 1,600 nm, depending on the voltage rating of device 270 (as described above with reference to fourth superlattice structure 212). The carbon concentration of fourth step graded layer 278 may be (e.g., vary between) about 1×10¹⁷ cm⁻³ to about 5×10¹⁹ cm⁻³, and more specifically, about 5×10¹⁷ cm⁻³ to about 1×10¹⁹ cm⁻³.

Therefore, the breakdown voltage enhancement and the current collapse mitigation may be achieved by the two partitions in III-N buffer layer 219 having fewer than six superlattice structures. As described above, voltage sustaining partition 219a of III-N buffer layer 219 may include step graded layers instead of superlattice structures. Furthermore, voltage sustaining partition 219a and back-barrier partition 219b are independent, or decoupled, from one another. Each partition may be optimized without affecting or relying on the other partition.

Referring now to FIG. 2L, a device 280 is shown including III-N buffer layer 219 that is formed having two step graded layers and four superlattice structures. Specifically, voltage sustaining partition 219a of III-N buffer layer 219 may be formed of first step graded layer 272, second step graded layer 274, third superlattice structure 210, and fourth superlattice structure 212 while back-barrier partition 219b of III-N buffer layer 219 may be formed of fifth superlattice structure 214, sixth superlattice structure 216, and III-N back-barrier layer 218. In various examples, voltage sustaining partition 219a of III-N buffer layer 219 may be formed of other configurations step graded layers and superlattice structures. For example, voltage sustaining partition 219a of III-N buffer layer 219 may be formed of any number of step graded layers and/or superlattice structures. In various examples, the step graded layers and superlattice structures may be interleaved in III-N buffer layer 219 (e.g., in voltage sustaining partition 219a).

Therefore, the breakdown voltage enhancement and the current collapse mitigation may be achieved by the two partitions in III-N buffer layer 219 having fewer than six superlattice structures. As described above, voltage sustaining partition 219a of III-N buffer layer 219 may include a mix of step graded layers and superlattice structures. Furthermore, voltage sustaining partition 219a and back-barrier partition 219b are independent, or decoupled, from one another. Each partition may be optimized without affecting or relying on the other partition.

Accordingly, III-N buffer layer 219 as described herein may be modified (e.g., number of superlattice structures, number of step graded layers, thickness, aluminum concentration, carbon concentration, etc.) for use in a variety of devices across a variety of voltages (e.g., 100 V to 1,200 V). That is, voltage sustaining partition 219a and/or the back-barrier partition 219b may be modified (e.g., number of layers, superlattice structures, number of step graded layers, stepped layers, etc.) for use in a variety of devices. Furthermore, as illustrated by the various examples, voltage sustaining partition 219a and back-barrier partition 219b may be customized independently of the other partition. Moreover, in some examples, III-N buffer layer 219 may not include the fifth superlattice structure 214 as part of back-barrier partition 219b.

Disclosed herein are devices and methods of forming a III-N buffer layer that manages the tradeoff between breakdown voltage and current collapse (or carrier confinement in the channel layer of III-N devices). As described above, a III-N buffer layer of the high electron mobility device is formed to include multiple layers (including one or more superlattice structures and/or one or more step graded layers) in which the concentration of a group III element (e.g., aluminum) decreases through the III-N buffer layer in a direction towards the active layers (e.g., GaN channel layer) of the high electron mobility device. Also, as described above with reference to various examples herein, the concentration of another group III element (e.g., gallium) increases through the III-N buffer layer in the direction towards the active layers of the high electron mobility device. In this manner, the III-N buffer layers in accordance with the present disclosure facilitate attaining active layers (e.g., GaN channel layer) of pristine quality over the III-N buffer layer that includes a base layer (e.g., AlN layer 204a) formed over a silicon substrate. In other words, various configurations of the III-N buffer layer (e.g., one or more superlattice structures, one or more step graded layers, or a combination thereof) described herein are devised to manage stress (or strain) associated with forming the III-N buffer layer such that desirable active layers for the high electron mobility device can be formed above the III-N buffer layer that is disposed above a substrate (e.g., a silicon substrate).

Moreover, a concentration of carbon (C) increases through the III-N buffer layer in the direction towards the active layers of the high electron mobility device. For instance, the back-barrier partition of the III-N buffer layer has a range of carbon concentrations between about 1×10¹⁹ cm⁻³ and about 1×10²² cm⁻³ whereas the voltage sustaining partition of the III-N buffer layer has a range of carbon concentrations between about 1×10¹⁷ cm⁻³ and about 5×10¹⁹ cm⁻³. The relatively high carbon concentrations in the back-barrier partition disposed underneath the channel layer may facilitate mitigating current collapse (facilitate confining carriers in the channel layer or facilitate reducing probability of carrier trapping). In other words, the III-N back-barrier layer 218 (e.g., carbon doped gallium nitride (GaN:C) layer with carbon concentration in the order of about 1×10¹⁹ cm⁻³ or about 1×10²² cm⁻³) underneath the III-N channel layer 220 (e.g., undoped GaN channel layer with carbon concentration in the order of about 1×10¹⁵ cm⁻³ or about 1×10¹⁶ cm⁻³) causes the energy band configuration of the III-N channel layer 220 to be tilted upward (e.g., sloped, bent) towards the interface between the undoped GaN channel layer and the carbon doped gallium nitride (GaN:C) back-barrier layer. In some examples, the conduction band in the undoped GaN channel layer may have a linear upward slope towards the interface, and thus may be regarded as forming a triangular quantum well structure. Such an energy band diagram may be attributed to the drastic difference in dopant concentration across the interface—e.g., the steep carbon concentration gradient across the interface between the undoped GaN channel layer (which may be regarded as an n-type semiconductor) and the carbon doped gallium nitride (GaN:C) back-barrier layer (which may be regarded as a heavily doped p-type semiconductor). The slope in the energy band (e.g., conduction band bending, conduction band tilting) in the undoped GaN channel layer renders the electrons (e.g., 2DEG) in the undoped GaN channel layer difficult (energetically unfavorable) to migrate toward the interface such that the electrons are confined near the surface of the undoped GaN channel layer facing the barrier layer (e.g., barrier layer 222). In this manner, the current collapse phenomenon may be mitigated or reduced. Further, one or more superlattice structures (e.g., sixth superlattice structure 216, the fifth superlattice structure 214, or both) disposed underneath the carbon doped gallium nitride (GaN:C) back-barrier layer are expected to repel (or push back) energetic electrons escaping the triangular quantum well because of a greater bandgap energy of the superlattice structures (e.g., bandgap energy of AlN layer of the superlattice structures). As such, the one or more superlattice structures of the back-barrier partition are expected to further mitigate current collapse (or to further facilitate carrier confinement in the channel layer).

Additionally, the III-N buffer layer may be formed to have thicker layers positioned closer to the semiconductor substrate and thinner layers positioned closer to the active layers of the high electron mobility device. In some examples, a thickness of each superlattice structure of the III-N buffer layer may decrease in the direction towards the active layers of the high electron mobility device. This decrease in thickness of the superlattice structures helps manage strain in the layers of the high electron mobility device.

The combination of gradually decreasing the aluminum concentration (e.g., average concentration), increasing carbon concentration, and/or decreasing the thickness of the superlattice structures of the III-N buffer layer in a direction towards the active layers of the high electron mobility device facilitates the functional separation of the III-N buffer layer. That is, the decoupling of the breakdown voltage enhancement and the current collapse mitigation is achieved by forming a two partition III-N buffer layer including a voltage sustaining partition and a back-barrier partition. Each of the two partitions may be customized without affecting the other partition. For example, the relatively higher average concentration of aluminum, lower concentration of carbon, and/or increased thickness of the voltage sustaining partition (e.g., lower superlattice structures such as first superlattice structure 206, second superlattice structure 208, third superlattice structure 210, fourth superlattice structure 212, and/or lower step graded layers such as first step graded layer 272 and/or second step graded layer 274) increases the breakdown voltage of a high electron mobility device (e.g., device 200). Also, for example, the relatively lower average concentration of aluminum, higher concentration of carbon, and/or decreased thickness of the back-barrier partition (e.g., upper superlattice structures such as fifth superlattice structure 214, sixth superlattice structure 216, and/or III-N back-barrier layer 218) mitigates the occurrence of current collapse in a high electron mobility device (e.g., device 200). This functional separation, or decoupling, allows the methods and devices described herein to be modified for use in a wide variety of devices having a voltage of about 100 V to about 1,200 V while managing stress in the high electron mobility device, increasing breakdown voltage, and decreasing current collapse.

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A semiconductor device comprising:
a substrate;
an aluminum gallium nitride (AlGaN) barrier layer over the substrate;
a gallium nitride (GaN) channel layer underneath the AlGaN barrier layer, the GaN channel layer including 2-dimensional electron gas (2DEG); and
a back-barrier structure underneath the GaN channel layer, the back-barrier structure including:
a GaN back-barrier layer underneath the GaN channel layer, the GaN back-barrier layer having a carbon concentration in a first range of carbon concentrations; and
a first superlattice (SL) structure underneath the GaN back-barrier layer, the first SL structure having a plurality of pairs of alternating a GaN layer and an aluminum nitride (AlN) layer, wherein the first SL structure has a first aluminum average composition and a first carbon concentration in the first range of carbon concentrations.

2. The semiconductor device of claim 1, wherein the first range of carbon concentrations is between about 5×10¹⁹ cm⁻³ and about 5×10²¹ cm⁻³.

3. The semiconductor device of claim 1, wherein the GaN back-barrier layer is exclusive of aluminum.

4. The semiconductor device of claim 1, wherein the first aluminum average composition of the first SL structure varies between about 4% and about 8%.

5. The semiconductor device of claim 1, wherein the back-barrier structure further includes:
a second SL structure underneath the first SL structure, the second SL structure having a plurality of pairs of alternating an AlGaN layer and an AlN layer, wherein the second SL structure has a second aluminum average composition greater than the first aluminum average composition and a second carbon concentration in the first range of carbon concentrations.

6. The semiconductor device of claim 5, wherein the second aluminum average composition of the second SL structure varies between about 30% and about 35%.

7. The semiconductor device of claim 5, further comprising:
a voltage-withstanding structure underneath the second SL structure, the voltage-withstanding structure including a plurality of SL structures, wherein individual SL structures of the plurality of SL structures include a plurality of pairs of alternating an AlGaN layer and an AlN layer.

8. The semiconductor device of claim 7, wherein the individual SL structures of the plurality of SL structures include respective third carbon concentrations in a second range of carbon concentrations less than the first range of carbon concentrations.

9. The semiconductor device of claim 8, wherein the second range of carbon concentrations is between about 5×10¹⁷ cm⁻³ and about 1×10¹⁹ cm⁻³.

10. The semiconductor device of claim 7, wherein the individual SL structures of the plurality of SL structures include respective third aluminum average compositions equal to or greater than the second aluminum average composition.

11. The semiconductor device of claim 7, wherein each SL structure of the plurality of SL structures has a third aluminum average composition such that an aluminum average composition in the plurality of SL structures increases in a direction towards the substrate.

12. The semiconductor device of claim 5, further comprising:
a voltage-withstanding structure underneath the second SL structure, the voltage-withstanding structure including a plurality of AlGaN layers.

13. The semiconductor device of claim 12, wherein individual AlGaN layers of the plurality of AlGaN layers include respective third carbon concentrations in a second range of carbon concentrations less than the first range of carbon concentrations.

14. The semiconductor device of claim 13, wherein the second range of carbon concentrations is between about 5×10¹⁷ cm⁻³ and about 1×10¹⁹ cm⁻³.

15. The semiconductor device of claim 12, wherein individual AlGaN layers of the plurality of AlGaN layers include respective third aluminum average compositions equal to or greater than the second aluminum average composition.

16. The semiconductor device of claim 12, wherein each AlGaN layer of the plurality of AlGaN layers has a third aluminum average composition such that an aluminum average composition in the plurality of AlGaN layers increases in a direction towards the substrate.

17. The semiconductor device of claim 1, further comprising:
a voltage-withstanding structure underneath the back-barrier structure, the voltage-withstanding structure including a plurality of SL structures, wherein individual SL structures of the plurality of SL structures include a plurality of pairs of alternating an AlGaN layer and an AlN layer.

18. The semiconductor device of claim 17, wherein the individual SL structures of the plurality of SL structures include respective third carbon concentrations in a second range of carbon concentrations less than the first range of carbon concentrations.

19. The semiconductor device of claim 18, wherein the second range of carbon concentrations is between about 5×10¹⁷ cm⁻³ and about 1×10¹⁹ cm⁻³.

20. The semiconductor device of claim 17, wherein the individual SL structures of the plurality of SL structures include respective third aluminum average compositions greater than the first aluminum average composition.

21. The semiconductor device of claim 17, wherein each SL structure of the plurality of SL structures has a third aluminum average composition such that an aluminum average composition in the plurality of SL structures increases in a direction towards the substrate.

22. The semiconductor device of claim 17, further comprising:
a gate structure over the AlGaN barrier layer, the gate structure operable to control the 2DEG in the GaN channel layer.

23. The semiconductor device of claim 22, wherein the gate structure includes a p-type doped GaN layer.

24. The semiconductor device of claim 17, further comprising:
a base layer underneath the voltage-withstanding structure, the base layer includes an AlN base layer and an AlGaN base layer over the AlN base layer.

25. The semiconductor device of claim 24, wherein:
the base layer is over the substrate; and
the substrate is a silicon substrate.

26. The semiconductor device of claim 1, further comprising:
a voltage-withstanding structure underneath the back-barrier structure, the voltage-withstanding structure including a plurality of AlGaN layers.

27. The semiconductor device of claim 26, wherein individual AlGaN layers of the plurality of AlGaN layers include respective third carbon concentrations in a second range of carbon concentrations less than the first range of carbon concentrations.

28. The semiconductor device of claim 27, wherein the second range of carbon concentrations is between about 5×10¹⁷ cm⁻³ and about 1×10¹⁹ cm⁻³.

29. The semiconductor device of claim 26, wherein individual AlGaN layers of the plurality of AlGaN layers include respective third aluminum average compositions greater than the first aluminum average composition.

30. The semiconductor device of claim 26, wherein each AlGaN layer of the plurality of AlGaN layers has a third aluminum average composition such that an aluminum average composition in the plurality of AlGaN layers increases in a direction towards the substrate.

31. The semiconductor device of claim 26, further comprising:
a gate structure over the AlGaN barrier layer, the gate structure operable to control the 2DEG in the GaN channel layer.

32. The semiconductor device of claim 31, wherein the gate structure includes a p-type doped GaN layer.

33. The semiconductor device of claim 26, further comprising:
a base layer underneath the voltage-withstanding structure, the base layer includes an AlN base layer and an AlGaN base layer over the AlN base layer.

34. The semiconductor device of claim 33, wherein:
the base layer is over the substrate; and
the substrate is a silicon substrate.

35. A semiconductor device comprising:
a substrate;
an aluminum gallium nitride (AlGaN) barrier layer over the substrate;
a first gallium nitride (GaN) layer underneath the AlGaN barrier layer, the first GaN layer including 2-dimensional electron gas (2DEG);
a second GaN layer underneath the first GaN layer, the second GaN layer having a carbon concentration in a first range of carbon concentrations, wherein the carbon concentration of the second GaN layer is greater than that of the first GaN layer by at least two orders of magnitude; and
a first superlattice (SL) structure underneath the second GaN layer, the first SL structure having a plurality of pairs of alternating a GaN layer and an aluminum nitride (AlN) layer, wherein the first SL structure has a first aluminum average composition and a first carbon concentration in the first range of carbon concentrations.

36. The semiconductor device of claim 35, wherein the first range of carbon concentrations is between about 5×10¹⁹ cm⁻³ and about 5×10²¹ cm⁻³.

37. The semiconductor device of claim 35, wherein the second GaN layer is exclusive of aluminum.

38. The semiconductor device of claim 35, wherein the second GaN back-barrier layer and the first SL structure form a composite back-barrier structure.

39. The semiconductor device of claim 35, further comprising:
a second SL structure underneath the first SL structure, the second SL structure having a plurality of pairs of alternating an AlGaN layer and an AlN layer, wherein the second SL structure has a second aluminum average composition greater than the first aluminum average composition and a second carbon concentration in the first range of carbon concentrations.

40. The semiconductor device of claim 39, wherein the second GaN layer, the first SL structure, and the second SL structure form a composite back-barrier structure.

41. The semiconductor device of claim 35, further comprising:
a plurality of SL structures underneath the first SL structure, wherein individual SL structures of the plurality of SL structures include a plurality of pairs of alternating an AlGaN layer and an AlN layer.

42. The semiconductor device of claim 41, wherein the individual SL structures of the plurality of SL structures include respective second carbon concentrations in a second range of carbon concentrations less than the first range of carbon concentrations.

43. The semiconductor device of claim 42, wherein the second range of carbon concentrations is between about 5×10¹⁷ cm⁻³ and about 1×10¹⁹ cm⁻³.

44. The semiconductor device of claim 43, wherein the individual SL structures of the plurality of SL structures include respective second aluminum average compositions greater than the first aluminum average composition.

45. The semiconductor device of claim 41, wherein each SL structure of the plurality of SL structures has a second aluminum average composition such that an aluminum average composition in the plurality of SL structures increases in a direction towards the substrate.

46. The semiconductor device of claim 41, further comprising:
a gate structure over the AlGaN barrier layer, the gate structure operable to control the 2DEG in the first GaN layer.

47. The semiconductor device of claim 46, wherein the gate structure includes a p-type doped GaN layer.

48. The semiconductor device of claim 41, further comprising:
an AlGaN base layer underneath the plurality of SL structures, the AlN base layer including a third aluminum average composition greater than the first aluminum average composition.

49. The semiconductor device of claim 48, further comprising:
an AlN base layer underneath the AlGaN base layer.

50. The semiconductor device of claim 35, further comprising:
a plurality of AlGaN layers underneath the first SL structure, wherein individual AlGaN layers of the plurality of AlGaN layers include respective second carbon concentrations in a second range of carbon concentrations less than the first range of carbon concentrations.

51. The semiconductor device of claim 50, wherein the second range of carbon concentrations is between about 5×10¹⁷ cm⁻³ and about 1×10¹⁹ cm⁻³.

52. The semiconductor device of claim 50, wherein individual AlGaN layers of the plurality of AlGaN layers include respective second aluminum average compositions greater than the first aluminum average composition.

53. The semiconductor device of claim 50, wherein each AlGaN layer of the plurality of AlGaN layers has a second aluminum average composition such that an aluminum average composition in the plurality of AlGaN layers increases in a direction towards the substrate.

54. The semiconductor device of claim 50, further comprising:
a gate structure over the AlGaN barrier layer, the gate structure operable to control the 2DEG in the first GaN layer.

55. The semiconductor device of claim 54, wherein the gate structure includes a p-type doped GaN layer.

56. The semiconductor device of claim 50, further comprising:
an AlGaN base layer underneath the plurality of AlGaN layers, the AlGaN base layer including a third aluminum average composition greater than the first aluminum average composition.

57. The semiconductor device of claim 56, further comprising:
an AlN base layer underneath the AlGaN base layer.

58. The semiconductor device of claim 35, wherein the substrate is a silicon substrate.
